(19) United States
(12) Patent Application Publication
(10) Pub. No.: US 2022/0350244 A1
(43) Pub. Date: Nov. 3, 2022

(54) PHOTOSENSITIVE RESIN COMPOSITION, CURED FILM, AND DISPLAY DEVICE

(71) Applicant: Toray Industries, Inc., Tokyo (JP)

(72) Inventors: Hideyuki Kobayashi, Otsu-shi Shiga (JP); Mitsuhito Suwa, Otsu-shi Shiga (JP); Yukinori Togo, Otsu-shi Shiga (JP)

(21) Appl. No.: 17/640,256

(22) PCT Filed: Sep. 3, 2020
(86) PCT No.: PCT/JP2020/033372

§ 371 Date: Mar. 3, 2022

(30) Foreign Application Priority Data
Sep. 11, 2019 (JP) 2019-165186

(51) Int. Cl. G03F 7/022; G03F 7/023; G03F 7/075

(52) U.S. Cl. CPC G03F 7/0226; G03F 7/0233; G03F 7/0755

(57) ABSTRACT

A photosensitive resin composition includes a siloxane resin (A), particles (B) having a median diameter of 0.2 to 0.6 μm, and a naphthoquinone diazide compound (C), wherein the siloxane resin (A) contains at least 20 to 60 mol % in total of a repeating unit represented by general formula (1):

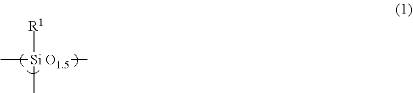

wherein R¹ represents an aryl group having 6 to 18 carbon atoms or an aryl group having 6 to 18 carbon atoms in which all or part of hydrogen is substituted.

### TECHNICAL FIELD

This disclosure relates to a photosensitive resin composition, a cured film using the photosensitive resin composition, a method of producing the cured film, and a display device.

### BACKGROUND

In general, a resin composition having light diffusibility is widely used as a material for diffusing light from a light emitting light source in lighting devices such as organic EL lighting and LED lighting, various display devices such as a laser display device and a liquid crystal display, and various other optical devices. In those applications, a resin composition having light diffusibility is required to have high reliability against heat and light, and a material in which a light diffusing agent is added to a highly reliable matrix resin (see, for example, Japanese Patent Laid-open Publication No. 2012-208424) has been proposed. On the other hand, for new applications such as organic EL lighting, performance such as thinning and bendability is also required, and no proposal has been made for a material that compositely satisfies these requirements. In addition, a technique of improving light diffusibility by forming an uneven pattern on a cured film having light diffusibility is known, and a resin composition having light diffusibility capable of accurately and easily forming an uneven pattern on a cured film (see, for example, Japanese Patent Laid-open Publication No. 2004-325861) has been proposed.

The resin composition having light diffusibility disclosed in JP '424 has a problem that bendability is insufficient. In addition, JP '861 discloses a composition having light diffusibility to form a fine uneven structure by an inkjet method. Since the composition contains fine particles, clogging occurs in ejection holes. Ejection failure is therefore likely to occur, and there is a problem that it is difficult to form a high-definition uneven structure.

It could therefore be helpful to provide a photosensitive resin composition from which a cured film can be obtained that has high reliability and excellent bendability, has excellent processability of uneven patterns, and has sufficient light diffusibility.

### SUMMARY

We thus provide:

A photosensitive resin composition includes a siloxane resin (A), particles (B) having a median diameter of 0.2 to 0.6 μm, and a naphthoquinone diazide compound (C), wherein the siloxane resin (A) contains at least 20 to 60 mol % in total of a repeating unit represented by general formula (1), and the content of the particles (B) having a median diameter of 0.2 to 0.6 μm in the total solid content of the photosensitive resin composition is 5 to 50 wt %:

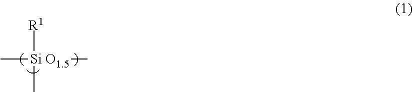

wherein R¹ represents an aryl group having 6 to 18 carbon atoms or an aryl group having 6 to 18 carbon atoms in which all or part of hydrogen is substituted.

We also provide a light diffusion layer including the photosensitive resin composition including a siloxane resin (A), particles (B) having a median diameter of 0.2 to 0.6 μm, and a naphthoquinone diazide compound (C), wherein the siloxane resin (A) contains at least 20 to 60 mol % in total of a repeating unit represented by general formula (1), and the content of the particles (B) having a median diameter of 0.2 to 0.6 μm in the total solid content of the photosensitive resin composition is 5 to 50 wt %:

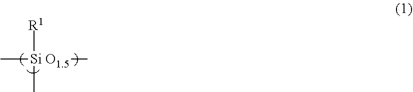

wherein R¹ represents an aryl group having 6 to 18 carbon atoms or an aryl group having 6 to 18 carbon atoms in which all or part of hydrogen is substituted.

We also further provide a cured film including a cured product of the photosensitive resin composition including a siloxane resin (A), particles (B) having a median diameter of 0.2 to 0.6 μm, and a naphthoquinone diazide compound (C), wherein the siloxane resin (A) contains at least 20 to 60 mol % in total of a repeating unit represented by general formula (1), and the content of the particles (B) having a median diameter of 0.2 to 0.6 μm in the total solid content of the photosensitive resin composition is 5 to 50 wt %:

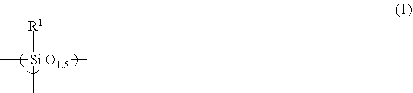

wherein R¹ represents an aryl group having 6 to 18 carbon atoms or an aryl group having 6 to 18 carbon atoms in which all or part of hydrogen is substituted.

We also further provide a method of producing a cured film, including (I) applying the photosensitive resin composition including a siloxane resin (A), particles (B) having a median diameter of 0.2 to 0.6 μm, and a naphthoquinone diazide compound (C), wherein the siloxane resin (A) contains at least 20 to 60 mol % in total of a repeating unit represented by general formula (1), and the content of the particles (B) having a median diameter of 0.2 to 0.6 μm in the total solid content of the photosensitive resin composition is 5 to 50 wt %:

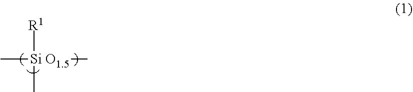

wherein R¹ represents an aryl group having 6 to 18 carbon atoms or an aryl group having 6 to 18 carbon atoms in which all or part of hydrogen is substituted onto a substrate to form a coating film; (II) exposing and developing the coating film; (III) re-exposing the developed coating film; and (IV) heating the re-exposed coating file.

We also further provide a substrate with a cured film including a substrate provided with a cured film patterned from the photosensitive resin composition a siloxane resin (A), particles (B) having a median diameter of 0.2 to 0.6 μm, and a naphthoquinone diazide compound (C), wherein the siloxane resin (A) contains at least 20 to 60 mol % in total of a repeating unit represented by general formula (1), and the content of the particles (B) having a median diameter of 0.2 to 0.6 μm in the total solid content of the photosensitive resin composition is 5 to 50 wt %:

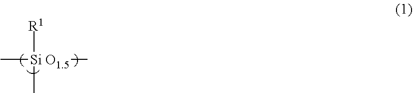

wherein R¹ represents an aryl group having 6 to 18 carbon atoms or an aryl group having 6 to 18 carbon atoms in which all or part of hydrogen is substituted on the substrate, the cured film having a haze of 20 to 98% per 1 μm of film thickness.

We also further provide a display device including the substrate with a cured film including a substrate provided with a cured film patterned from the photosensitive resin composition a siloxane resin (A), particles (B) having a median diameter of 0.2 to 0.6 μm, and a naphthoquinone diazide compound (C), wherein the siloxane resin (A) contains at least 20 to 60 mol % in total of a repeating unit represented by general formula (1), and the content of the particles (B) having a median diameter of 0.2 to 0.6 μm in the total solid content of the photosensitive resin composition is 5 to 50 wt %:

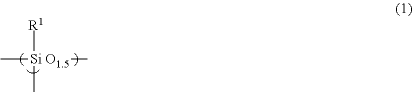

wherein R¹ represents an aryl group having 6 to 18 carbon atoms or an aryl group having 6 to 18 carbon atoms in which all or part of hydrogen is substituted on the substrate, the cured film having a haze of 20 to 98% per 1 μm of film thickness.

Our photosensitive resin composition is excellent in light diffusibility, heat resistance, and light resistance and not only has good bendability but also can accurately form an uneven pattern by a photosensitive method. A cured film having high light diffusibility, excellent heat resistance and light resistance, and good bendability can be obtained with our photosensitive resin composition.

### BRIEF DESCRIPTION OF THE DRAWINGS

FIG. 1 is a cross-sectional view showing one aspect of a substrate with a cured film including a patterned cured film.

FIG. 2 is a cross-sectional view showing one aspect of a substrate with a cured film including a patterned cured film and a black layer.

### DESCRIPTION OF REFERENCE SIGNS

### 1: Substrate

2: Cured film
3: Black layer

### DETAILED DESCRIPTION

Our photosensitive resin composition contains a siloxane resin (A), particles (B) having a median diameter of 0.2 to 0.6 μm, and a naphthoquinone diazide compound (C). Since the siloxane resin (A) is contained, thermal polymerization (condensation) of the siloxane resin proceeds by heating to improve the crosslinking density so that a cured film excellent in heat resistance and light resistance can be obtained. In addition, since the particles (B) having a median diameter of 0.2 to 0.6 μm are contained, good light diffusibility can be achieved. Further, since the naphthoquinone diazide compound (C) is contained, positive photosensitivity is exhibited in which an exposed portion is removed with a developer.

### Siloxane Resin (A)

The siloxane resin (A) is a hydrolysis/dehydration condensation product of an organosilane and contains 20 to 60 mol % in total of a repeating unit represented by general formula (1). When the siloxane resin contains 20 to 60 mol % in total of the repeating unit represented by general formula (1), the siloxane resin can be easily compatible with other components so that excellent resolution can be exhibited.

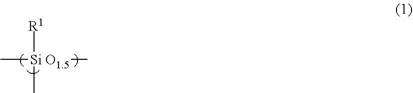

wherein R¹ represents an aryl group having 6 to 18 carbon atoms or an aryl group having 6 to 18 carbon atoms in which all or part of hydrogen is substituted.

Furthermore, it is more preferable to contain 30 to 50 mol % in total of the repeating unit represented by general formula (1). The content ratio of the organosilane unit having a repeating unit represented by general formula (1) can be determined by ²⁹Si-NMR measurement. That is, it can be determined by calculating the ratio of the integral value of Si derived from the organosilane unit having the repeating unit represented by general formula (1) to the integral value of the entire Si derived from the organosilane.

In addition, the siloxane resin preferably contains 5 to 20 mol % in total of a repeating unit represented by general formula (2). Since 5 mol % or more of the repeating unit represented by general formula (2) is contained, the siloxane resin is quickly crosslinked at the time of heating, and fluidity can be suppressed so that variations in processing dimensions before and after heating can be suppressed. In addition, since 20 mol % or less of the repeating unit represented by general formula (2) is contained, the silanol group amount can be prevented from being excessive, and the storage stability of the photosensitive resin composition can be improved. The content ratio of the organosilane unit represented by general formula (2) can be determined by performing ²⁹Si-NMR measurement and calculating the ratio of the integral value of Si derived from the organosilane unit having general formula (2) to the integral value of the entire Si derived from the organosilane:

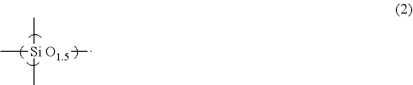

In addition, the siloxane resin preferably contains 1 to 20 mol % in total of a repeating unit represented by general formula (3). Since 1 mol % or more of the repeating unit represented by general formula (3) is contained, the refractive index of the siloxane resin (A) decreases, and interface reflection with the particles (B) having a median diameter of 0.2 to 0.6 μm is improved so that good light diffusibility can be exhibited. Furthermore, it is also possible that the cured film has good bendability. On the other hand, when the content of the repeating unit represented by general formula (3) is 20 mol % or less, compatibility between the siloxane resin and other components in the composition can be prevented from being reduced, and good resolution can be achieved. The content ratio of the organosilane unit represented by general formula (3) can be determined by performing ²⁹Si-NMR measurement and calculating the ratio of the integral value of Si derived from the organosilane unit having general formula (3) to the integral value of the entire Si derived from the organosilane. When repeating units other than the repeating units represented by general formulae (1) to (3) are contained, the content thereof is preferably 10 to 50 mol %.

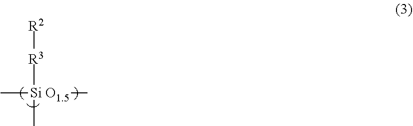

wherein R² represents an alkyl group, an alkenyl group, an aryl group, or an arylalkyl group wherein each group has 1 to 10 carbon atoms and in which all or part of hydrogen is substituted with fluorine. R³ represents a single bond, —O—, —CH₂—CO—, —CO—, or —O—CO—.

R² is preferably an alkyl group in which all or part of hydrogen is substituted with fluorine from the viewpoint of further reducing the refractive index of the siloxane resin. In this example, the number of carbon atoms in the alkyl group is preferably 1 to 6. R³ is preferably a group selected from an alkyl group having 1 to 6 carbon atoms and an acyl group having 2 to 10 carbon atoms from the viewpoint of reducing the refractive index of the siloxane resin.

The repeating units represented by general formulae (1) to (3) are respectively derived from alkoxysilane compounds represented by general formulae (4) to (6). That is, a siloxane resin containing the repeating unit represented by general formula (1) and/or the repeating unit represented by general formula (2) and the repeating unit represented by general formula (3) can be obtained by hydrolyzing and polycondensing a plurality of alkoxysilane compounds containing an alkoxysilane compound represented by general formula (4) and/or an alkoxysilane compound represented by general formula (5) and an alkoxysilane compound represented by general formula (6). Still another alkoxysilane compound may be used.

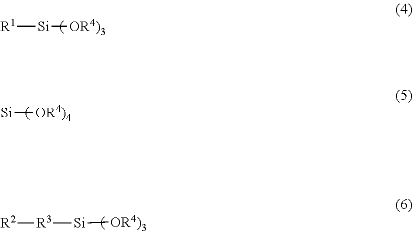

In general formulae (4) to (6), R¹, R², and R³ represent the same groups as R¹, R², and R³ in general formulae (1) to (3), respectively. R⁴ may be the same or different and represents a monovalent organic group having 1 to 20 carbon atoms and is preferably an alkyl group having 1 to 6 carbon atoms.

Examples of the organosilane compound represented by general formula (4) include phenyltrimethoxysilane, phenyltriethoxysilane, phenyltripropoxysilane, naphthyltrimethoxysilane, naphthyltriethoxysilane, and naphthyltripropoxysilane. Two or more of these compounds may be used.

Examples of the organosilane compound represented by general formula (5) include tetramethoxysilane, tetraethoxysilane, and tetrapropoxysilane. Two or more of these compounds may be used.

Examples of the organosilane compound represented by general formula (6) include trifluoropropyltrimethoxysilane, trifluoropropyltriethoxysilane, perfluoropentyltrimethoxysilane, perfluoropentyltriethoxysilane, tridecafluorooctyltrimethoxysilane, tridecafluorooctyltriethoxysilane, tridecafluorooctyltripropoxysilane, tridecafluorooctyltriisopropoxysilane, heptadecafluorodecyltrimethoxysilane, and heptadecafluorodecyltriethoxysilane. Two or more of these compounds may be used.

Examples of an organosilane compound other than the compounds represented by general formulae (4) to (6) include methyltrimethoxysilane, methyltriethoxysilane, methyltripropoxysilane, methyltriisopropoxysilane, methyltributoxysilane, ethyltrimethoxysilane, ethyltriethoxysilane, hexyltrimethoxysilane, octadecyltrimethoxysilane, octadecyltriethoxysilane, 3-aminopropyltrimethoxysilane, 3-aminopropyltriethoxysilane, N-(2-aminoethyl)-3-aminopropyltrimethoxysilane, 3- chloropropyltrimethoxysilane, 3-(N,N-glycidyl)aminopropyltrimethoxysilane, 3-glycidoxypropyltrimethoxysilane, γ-aminopropyltrimethoxysilane, γ-aminopropyltriethoxysilane, N-β-(aminoethyl)-γ-aminopropyltrimethoxysilane, β-cyanoethyltriethoxysilane, glycidoxymethyltrimethoxysilane, glycidoxymethyltriethoxysilane, α-glycidoxyethyltrimethoxysilane, α-glycidoxyethyltriethoxysilane, β-glycidoxypropyltrimethoxysilane, β-glycidoxypropyltriethoxysilane, γ-glycidoxypropyltrimethoxysilane, γ-glycidoxypropyltriethoxysilane, γ-glycidoxypropyltripropoxysilane, γ-glycidoxypropyltriisopropoxysilane, γ-glycidoxypropyltributoxysilane, γ-glycidoxypropyltri(methoxyethoxy)silane, α-glycidoxybutyltrimethoxysilane, α-glycidoxybutyltriethoxysilane, β-glycidoxybutyltrimethoxysilane, β-glycidoxybutyltriethoxysilane, γ-glycidoxybutyltrimethoxysilane, γ-glycidoxybutyltriethoxysilane, σ-glycidoxybutyltrimethoxysilane, σ-glycidoxybutyltriethoxysilane, (3,4-epoxycyclohexyl)methyltrimethoxysilane, (3,4-epoxycyclohexyl)methyltriethoxysilane, 2-(3,4-epoxycyclohexyl)ethyltripropoxysilane, 2-(3,4 -epoxycyclohexyl)ethyltributoxysilane, 2-(3,4-epoxycyclohexyl)ethyltrimethoxysilane, 2-(3,4-epoxycyclohexyl)ethyltriethoxysilane, 2-(3,4-epoxycyclohexyl)ethyltriphenoxysilane, 3-(3,4 -epoxycyclohexyl)propyltrimethoxysilane, 3-(3,4 -epoxycyclohexyl)propyltriethoxysilane, 4-(3,4-epoxycyclohexyl)butyltrimethoxysilane, 4-(3,4-epoxycyclohexyl)butyltriethoxysilane, dimethyldimethoxysilane, dimethyldiethoxysilane, γ-glycidoxypropylmethyldimethyldimethoxysilane, γ-aminopropylmethyldimethoxysilane, γ-aminopropylmethyldimethoxysilane, N-(2-aminoethyl)-3-aminopropylmethyldimethoxysilane, glycidoxymethyldimethoxysilane, glycidoxymethylmethyldiethoxysilane, α-glycidoxyethylmethyldimethoxysilane, α-glycidoxyethylmethyldiethoxysilane, β-glycidoxyethylmethyldimethoxysilane, β-glycidoxyethylmethyldiethoxysilane, α-glycidoxypropylmethyldimethoxysilane, α-glycidoxypropylmethyldiethoxysilane, (3-glycidoxypropylmethyldimethoxysilane, β-glycidoxypropylmethyldiethoxysilane, γ-glycidoxypropylmethyldimethoxysilane, γ-glycidoxypropylmethyldiethoxysilane, γ-glycidoxypropylmethyldipropoxysilane, P-glycidoxypropylmethyldibutoxysilane, y-glycidoxypropylmethyldi(methoxyethoxy)silane, γ-glycidoxypropylethyldimethoxysilane, γ-glycidoxypropylethyldiethoxysilane, 3-chloropropylmethyldimethoxysilane, 3-chloropropylmethyldiethoxysilane, cyclohexylmethyldimethoxysilane, octadecylmethyldimethoxysilane, 3-trimethoxysilylpropylsuccinic anhydride, 3-triethoxysilylpropylsuccinic anhydride, 3-triphenoxysilylpropylsuccinic anhydride, 3-trimethoxysilylpropylcyclohexyldicarboxylic anhydride, and 3-trimethoxysilylpropylphthalic anhydride. Two or more of these compounds may be used.

The weight average molecular weight (Mw) of the siloxane resin (A) is preferably 1,000 or more, more preferably 2,000 or more from the viewpoint of the coating properties. On the other hand, the Mw of the siloxane resin (A) is preferably 50,000 or less, more preferably 20,000 or less from the viewpoint of developability. The “Mw” of the siloxane resin (A) refers to a polystyrene equivalent value measured by gel peremission chromatography (GPC).

The content of the siloxane resin (A) can be arbitrarily set according to the desired film thickness and application. It is preferably 10 to 80 wt % in the solid content of the photosensitive resin composition. The content of the siloxane resin (A) is more preferably 20 wt % or more, still more preferably 30 wt % or more in the solid content of the photosensitive resin composition. On the other hand, the content of the siloxane resin (A) is more preferably 70 wt % or less in the solid content of the photosensitive resin composition.

The siloxane resin (A) can be obtained by hydrolyzing the above-mentioned organosilane compound and then subjecting the hydrolysate to a dehydration condensation reaction in the presence or absence of a solvent.

Various conditions for the hydrolysis can be set in consideration of the reaction scale, the size and shape of the reaction container and the like according to physical properties suited for intended uses. Examples of the various conditions include an acid concentration, a reaction temperature, and a reaction time.

In the hydrolysis reaction, an acid catalyst such as hydrochloric acid, acetic acid, formic acid, nitric acid, oxalic acid, hydrochloric acid, sulfuric acid, phosphoric acid, polyphosphoric acid, polycarboxylic acid or an anhydride thereof, or an ion exchange resin can be used. Among them, an acidic aqueous solution containing formic acid, acetic acid, and/or phosphoric acid is preferable.

When an acid catalyst is used in the hydrolysis reaction, the addition amount of the acid catalyst is preferably 0.05 parts by weight or more, more preferably 0.1 parts by weight or more, based on 100 parts by weight of the total alkoxysilane compound used in the hydrolysis reaction, from the viewpoint of more rapidly progressing the hydrolysis. On the other hand, from the viewpoint of appropriately adjusting the progress of the hydrolysis reaction, the addition amount of the acid catalyst is preferably 20 parts by weight or less, more preferably 10 parts by weight or less, based on 100 parts by weight of the total alkoxysilane compound. The total amount of alkoxysilane compound refers to an amount including all of an alkoxysilane compound, a hydrolysate thereof, and a condensate thereof, and the same applies hereinafter.

The hydrolysis reaction can be carried out in a solvent. The solvent can be appropriately selected in consideration of the stability, wettability, volatility and the like of the photosensitive resin composition. Examples of the solvent include: alcohols such as methanol, ethanol, propanol, isopropanol, butanol, isobutanol, t-butanol, pentanol, 4-methyl-2-pentanol, 3-methyl-2-butanol, 3-methyl-3-methoxy-1-butanol, and diacetone alcohol; glycols such as ethylene glycol and propylene glycol; ethers such as ethylene glycol monomethyl ether, ethylene glycol monoethyl ether, propylene glycol monomethyl ether, propylene glycol monoethyl ether, propylene glycol monopropyl ether, propylene glycol monobutyl ether, propylene glycol mono-t-butyl ether, ethylene glycol dimethyl ether, ethylene glycol diethyl ether, ethylene glycol dibutyl ether, and diethyl ether; ketones such as methyl ethyl ketone, acetyl acetone, methyl propyl ketone, methyl butyl ketone, methyl isobutyl ketone, diisobutyl ketone, cyclopentanone, and 2-heptanone; amides such as dimethylformamide and dimethylacetamide; acetates such as ethyl acetate, propyl acetate, butyl acetate, isobutyl acetate, ethylene glycol monoethyl ether acetate, propylene glycol monomethyl ether acetate, 3-methoxybutyl acetate, 3-methyl-3-methoxybutyl acetate, methyl lactate, ethyl lactate, and butyl lactate; aromatic and aliphatic hydrocarbons such as toluene, xylene, hexane, and cyclohexane; γ-butyrolactone, N-methyl-2-pyrrolidone, and dimethyl sulfoxide. Two or more of these compounds may be used.

Among them, from the viewpoint of transmittance, crack resistance, and the like of the cured film, diacetone alcohol, propylene glycol monomethyl ether, propylene glycol monomethyl ether acetate, propylene glycol monoethyl ether, propylene glycol monopropyl ether, propylene glycol monobutyl ether, propylene glycol mono-t-butyl ether, γ-butyrolactone and the like are preferably used.

When a solvent is formed through the hydrolysis reaction, the hydrolyzation can be carried out without a solvent. After completion of the hydrolysis reaction, it is also preferable to further add a solvent to adjust the concentration to be appropriate for the photosensitive resin composition. In addition, it is also possible to distill and remove the whole amount or part of the produced alcohol and the like by heating and/or reducing the pressure after hydrolysis and then add a suitable solvent.

When a solvent is used in the hydrolysis reaction, the amount of the solvent to be added is preferably 50 parts by weight or more, more preferably 80 parts by weight or more, based on 100 parts by weight of the total alkoxysilane compound, from the viewpoint of suppressing generation of a gel. On the other hand, from the viewpoint of more rapidly progressing the hydrolysis, the addition amount of the solvent is preferably 500 parts by weight or less, more preferably 200 parts by weight or less, based on 100 parts by weight of the total alkoxysilane compound.

The water used for the hydrolysis reaction is preferably ion-exchanged water. The amount of water can be arbitrarily set but is preferably 1.0 to 4.0 mol with respect to 1 mol of the total alkoxysilane compound.

Examples of the method for the dehydration condensation reaction include a method in which a silanol compound solution obtained by the hydrolysis reaction of the organosilane compound is heated as it is. The heating temperature is preferably not lower than 50° C. and not higher than the boiling point of the solvent, and the heating time is preferably 1 to 100 hours. Moreover, it is also possible to reheat the reaction liquid or add a base catalyst to the reaction liquid to enhance the degree of polymerization of the siloxane resin. After the hydrolysis, it is also possible, depending on the purpose, to distill off an appropriate amount of products such as alcohols under heating and/or reduced pressure and then add a suitable solvent.

From the viewpoint of storage stability of the photosensitive resin composition, it is preferable that the siloxane resin solution after hydrolysis and dehydration condensation do not contain the catalyst, and the catalyst can be removed as necessary. As the method of removing the catalyst, a process by water washing or with ion exchange resin is preferable from the viewpoint of ease of operation and removal characteristic. The water washing refers to a method in which a solution of the siloxane resin is diluted with an appropriate hydrophobic solvent and then washed with water several times and the obtained organic layer is concentrated by an evaporator or the like. Furthermore, the process with ion exchange resin refers to a method in which a solution of the siloxane resin obtained is brought into contact with an appropriate ion exchange resin.

The refractive index of the siloxane resin (A) at a wavelength of 587.5 nm is preferably 1.35 to 1.55. When the refractive index of the siloxane resin (A) is 1.35 or more, excessive interface reflection between the siloxane resin (A) and the particles (B) having a median diameter of 0.2 to 0.6 μm can be suppressed, and the resolution can be further improved. The refractive index of the siloxane resin (A) is more preferably 1.40 or more. On the other hand, by setting the refractive index of the siloxane resin (A) to 1.55 or less, interface reflection between the particles (B) having a median diameter of 0.2 to 0.6 μm and the siloxane resin (A) can be increased, and light diffusibility can be further improved. The refractive index of the siloxane resin (A) is measured by irradiating a cured film of the siloxane resin formed on a silicon wafer with light having a wavelength of 587.5 nm from a direction perpendicular to a surface of the cured film under atmospheric pressure at 20° C. using a prism coupler (PC-2000 (manufactured by Metricon Corporation)). However, the value is rounded off to two decimals. The cured film of the siloxane resin is produced by spin-coating a siloxane resin solution in which the siloxane resin is dissolved in an organic solvent to have a solid concentration of 40 wt % on a silicon wafer, drying the solution on a hot plate at 90° C. for 2 minutes, and then curing the solution in air at 170° C. for 30 minutes using an oven. When the photosensitive resin composition contains two or more kinds of the siloxane resin (A), the refractive index of at least one kind is preferably in the above range.

### Particles (B) Having a Median Diameter of 0.2 to 0.6 μm

The particles (B) having a median diameter of 0.2 to 0.6 μm can scatter incident light in a wide range and exhibit sufficient light diffusibility. In particles having a median diameter of less than 0.2 μm, scattering of light by the particles is insufficient, and sufficient light diffusibility cannot be secured. On the other hand, when particles having a median diameter of more than 0.6 μm are used, light scattering is concentrated in the forward direction, and thus sufficient light diffusibility cannot be secured.

Examples of the particles (B) having a median diameter of 0.2 to 0.6 μm include compounds selected from titanium dioxide, zirconium oxide, aluminum oxide, talc, isinglass (mica), white carbon, magnesium oxide, zinc oxide, barium carbonate, and composite compounds thereof. Two or more of these may be contained. Among them, it is preferable to contain titanium dioxide, which has high light diffusibility and is easy to use industrially, and zirconia oxide.

The particles (B) having a median diameter of 0.2 to 0.6 μm may be subjected to surface treatment. Surface treatment with Al, Si, and/or Zr is preferable so that the dispersibility of the particles (B) having a median diameter of 0.2 to 0.6 μm in the photosensitive resin composition can be improved, and the light resistance and heat resistance of the cured film can be further improved. The median diameter refers to an average primary particle diameter of the particles (B) having a median diameter of 0.2 to 0.6 μm calculated from a particle size distribution measured by a laser diffraction method.

Examples of titanium dioxide used as the particles (B) having a median diameter of 0.2 to 0.6 μm include R-960 (SiO₂/Al₂O₃ surface treatment, median diameter: 0.21 μm) manufactured by DuPont de Nemours, Inc., CR-97 (Al₂O₃/ZrO₂ surface treatment, median diameter: 0.25 μm) manufactured by ISHIHARA SANGYO KAISHA, LTD., JR-301 (Al₂O₃ surface treatment, median diameter: 0.30 μm) manufactured by Tayca Corporation, JR-405 (Al₂O₃ surface treatment, median diameter: 0.21 μm) manufactured by Tayca Corporation, JR-600A (Al₂O₃ surface treatment, median diameter: 0.25 μm) manufactured by Tayca Corporation, and JR-603 (Al₂O₃/ZrO₂ surface treatment, median diameter: 0.28 μm) manufactured by Tayca Corporation, examples of zirconia oxide include 3YI-R (Al₂O₃ surface treatment, median system: 0.50 μm) manufactured by Toray Industries, Inc., and examples of aluminum oxide include AO-502 (no surface treatment, median diameter: 0.25 μm) manufactured by Admatechs Co., Ltd. Two or more of these may be contained.

The refractive index of the particles (B) having a median diameter of 0.2 to 0.6 μm is preferably 1.70 to 2.90. By setting the refractive index of the particles (B) having a median diameter of 0.2 to 0.6 μm to 1.70 or more, interface reflection between the particles (B) having a median diameter of 0.2 to 0.6 μm and the siloxane resin (A) can be increased, and the reflectance can be further improved. The refractive index of the particles (B) having a median diameter of 0.2 to 0.6 μm is more preferably 2.20 or more, still more preferably 2.40 or more. On the other hand, by setting the refractive index of the particles (B) having a median diameter of 0.2 to 0.6 μm to 2.90 or less, excessive interface reflection between the siloxane resin (A) and the particles (B) having a median diameter of 0.2 to 0.6 μm can be suppressed, and the resolution can be further improved. The refractive index of the particles (B) having a median diameter of 0.2 to 0.6 μm means a typical refractive index of a material constituting the particles. The refractive index of the material constituting the particles can be measured by forming a cured film of the material constituting the particles on a silicon wafer by vacuum vapor deposition, sputtering or the like and irradiating the cured film surface with light having a wavelength of 587.5 nm from a direction perpendicular to the surface of the cured film under atmospheric pressure at 20° C. using a prism coupler (PC-2000 (manufactured by Metricon Corporation)). However, the value is rounded off to two decimals. The measurement wavelength is a standard wavelength of 587.5 nm. When two or more kinds of the particles (B) having a median diameter of 0.2 to 0.6 μm are contained, the refractive index of at least one kind is preferably in the above range.

The difference in refractive index at a wavelength of 587.5 nm between the siloxane resin (A) and the particles (B) having a median diameter of 0.2 to 0.6 μm is preferably 0.20 to 1.40. When the difference in refractive index is 0.20 or more, interface reflection between the siloxane resin (A) and the particles (B) having a median diameter of 0.2 to 0.6 μm increases, and light diffusibility can be improved. The difference in refractive index is more preferably 0.50 or more, still more preferably 1.00 or more. On the other hand, when the difference in refractive index is 1.40 or less, excessive interface reflection between the siloxane resin (A) and the particles (B) having a median diameter of 0.2 to 0.6 μm can be suppressed, and the resolution can be further improved. The difference in refractive index is more preferably 1.35 or less.

From the viewpoint of further improving the diffusibility, the content of the particles (B) having a median diameter of 0.2 to 0.6 μm in the photosensitive resin composition is preferably 5 wt % or more, more preferably 10 wt % or more, still more preferably 20 wt % or more, and still more preferably 40 wt % or more in the solid content. On the other hand, the content of the particles (B) having a median diameter of 0.2 to 0.6 μm is preferably 65 wt % or less, more preferably 60 wt % or less, in the solid content from the viewpoint of suppressing development residues to form a pattern with higher resolution. The solid content as used herein means all components except volatile components such as solvents among components contained in the photosensitive resin composition. The amount of the solid content can be determined by heating the photosensitive resin composition at 170° C. for 30 minutes to evaporate the volatile components and measuring the residue.

When the photosensitive resin composition contains a pigment dispersant together with the particles (B) having a median diameter of 0.2 to 0.6 μm, the dispersibility of the particles (B) having a median diameter of 0.2 to 0.6 μm in the photosensitive resin composition can be improved. The pigment dispersant may be appropriately selected depending on a type and surface conditions of the particles (B) having a median diameter of 0.2 to 0.6 μm to be used. The pigment dispersant preferably contains an acid group and/or a basic group. Examples of a commercially available pigment dispersant include “Disperbyk” (registered trademark) 106, 108, 110, 180, 190, 2001, 2155, 140, and 145 (the above are trade names, manufactured by BYK Japan KK). Two or more of these may be contained.

### Naphthoquinone Diazide Compound (C)

Examples of the naphthoquinone diazide compound include a compound having a phenolic hydroxy group bonded to sulfonic acid of naphthoquinone diazide through ester linkage.

The naphthoquinone diazide compound (C) to be used is not particularly limited, but a compound having a phenolic hydroxy group bonded to sulfonic acid of naphthoquinone diazide through ester linkage is preferable. Examples of the compound with a phenolic hydroxy group to be used here include Bis-Z, BisOC-Z, BisOPP-Z, BisP-CP, Bis26X-Z, BisOTBP-Z, BisOCHP-Z, BisOCR-CP, BisP-MZ, BisP-EZ, Bis26X-CP, BisP-PZ, BisP-IPZ, BisCR-IPZ, BisOCP-IPZ, BisOIPP-CP, Bis26X-IPZ, BisOTBP-CP, TekP-4HBPA (tetrakis P-DO-BPA), TrisP-HAP, TrisP-PA, BisOFP-Z, BisRS-2P, BisPG-26X, BisRS-3P, BisOC-OCHP, BisPC-OCHP, Bis25X-OCHP, Bis26X-OCHP, BisOCHP-OC, Bis236T-OCHP, methylene tris-FR-CR, BisRS-26X, and BisRS-OCHP (trade names, manufactured by Honshu Chemical Industry Co., Ltd.); BIR-OC, BIP-PC, BIR-PC, BIR-PTBP, BIR-PCHP, BIP-BIOC-F, 4PC, BIR-BIPC-F, and TEP-BIP-A (trade names, manufactured by Asahi Organic Chemicals Industry Co., Ltd.); 4,4′-sulfonyldiphenol (manufactured by Wako Pure Chemical Industries, Ltd.); and BPFL (trade name, manufactured by JFE Chemical Corporation).

Among them, examples of preferred compounds having a phenolic hydroxy group include Bis-Z, BisP-EZ, TekP-4HBPA, TrisP-HAP, TrisP-PA, BisOCHP-Z, BisP-MZ, BisP-PZ, BisP-IPZ, BisOCP-IPZ, BisP-CP, BisRS-2P, BisRS-3P, BisP-OCHP, methylene tris-FR-CR, BisRS-26X, BIP-PC, BIR-PC, BIR-PTBP, and BIR-BIPC-F. Among them, examples of particularly preferred compounds having a phenolic hydroxy group include Bis-Z, TekP-4HBPA, TrisP-HAP, TrisP-PA, BisRS-2P, BisRS-3P, BIR-PC, BIR-PTBP, BIR-BIPC-F, 4,4′-sulfonyldiphenol, and BPFL. A compound obtained by introducing 4-naphthoquinone diazide sulfonate into these compounds having a phenolic hydroxy group through an ester bond can be exemplified as a preferable compound, but other compounds can also be used. The molecular weight of the naphthoquinone diazide compound (C) is preferably 300 to 1,500, more preferably 350 to 1,200. When the molecular weight is 300 or more, an effect of inhibiting dissolution of an unexposed portion is obtained. In addition, by setting the molecular weight to 1,500 or less, a good pattern without a development residue or the like can be obtained.

These naphthoquinone diazide compounds (C) may be used alone or in combination of two or more thereof

The content of these naphthoquinone diazide compounds (C) is preferably 1 to 30 parts by weight with respect to the siloxane resin (A). When the content is 1 part by weight or more, a pattern can be formed with practical sensitivity. When the content is 30 parts by weight or less, a resin composition excellent in pattern resolution is obtained.

When the naphthoquinone diazide compound (C) is added, an unreacted photosensitizer may remain in an unexposed portion, and the film may be colored after thermal curing. To obtain a cured film with less coloration, it is preferable to irradiate the entire surface of the film after development with ultraviolet rays and heat the film.

If necessary, the photosensitive resin composition may further contain a crosslinking agent, an adhesion improving agent, a solvent, a surfactant, a dissolution inhibitor, a stabilizer, an antifoaming agent, and the like.

When the photosensitive resin composition contains a crosslinking agent, crosslinking of the siloxane resin is promoted during thermal curing, and the degree of crosslinking of the cured film is increased. Therefore, a decrease in pattern resolution due to melting of the fine pattern during thermal curing is suppressed. Examples of the curing agent include a nitrogen-containing organic substance, a silicone resin curing agent, an isocyanate compound and a polymer thereof, a methylolated melamine derivative, a methylolated urea derivative, various metal alcohol rates, various metal chelate compounds, a thermal acid generator, and a photoacid generator. Two or more of these may be contained. Among them, a methylolated melamine derivative, a methylolated urea derivative, and a photoacid generator are preferably used from the viewpoint of the stability of the curing agent, the processability of the coating film and the like. The photoacid generator is a compound that generates an acid upon bleaching exposure and is a compound that generates an acid upon irradiation with rays at an exposure wavelength of 365 nm (i-line), 405 nm (h-line), or 436 nm (g-line) or mixed rays thereof Therefore, there is a possibility that an acid is generated even in pattern exposure using a similar light source, but since the exposure amount is smaller in pattern exposure than in bleaching exposure, only a small amount of acid is generated, which is not a problem. The acid to be generated is preferably a strong acid such as a perfluoroalkylsulfonic acid or p-toluenesulfonic acid, and the naphthoquinone diazide compound (C) that generates carboxylic acid does not have the function of the photoacid generator described herein and is different from the curing agent.

When the photosensitive resin composition contains an adhesion improving agent, adhesion to a substrate is improved, and a highly reliable cured film can be obtained. Examples of the adhesion improving agent include an alicyclic epoxy compound and a silane coupling agent. Among them, the silane coupling agent has high heat resistance and thus can further suppress color change after heating, which is preferable.

Examples of the silane coupling agent include (3,4-epoxycyclohexyl)methyltrimethoxysilane, (3,4-ep oxycyclohexyl)methyltriethoxysilane, 2-(3,4-epoxycyclohexyl)ethyltripropoxysilane, 2-(3,4-epoxycyclohexyl)ethyltributoxysi lane, 2-(3,4-epoxycyclohexyl)ethyltrimethoxysilane, 2-(3,4-epoxycyclohexyl)ethyltriethoxysilane, 2-(3,4-epoxycyclohexyl)ethyltriphenoxysilane, 3-(3,4-epoxycyclohexyl)propyltrimethoxysilane, 3-(3,4-epoxycyclohexyl)propyltriethoxysilane, 4-(3,4-epoxycyclohexyl)butyltrimethoxysilane, and 4-(3,4-epoxycyclohexyl)butyltriethoxysilane. Two or more of these may be contained.

The content of the adhesion improving agent in the photosensitive resin composition is preferably 0.1 wt % or more, more preferably 1 wt % or more, in the solid content from the viewpoint of further improving the adhesion to the substrate. On the other hand, the content of the adhesion improving agent is preferably 20 wt % or less, more preferably 10 wt % or less, in the solid content from the viewpoint of further suppressing the color change due to heating.

Since the photosensitive resin composition contains the solvent, the viscosity can be easily adjusted to a viscosity suitable for coating, and the uniformity of the coating film can be improved. It is preferable to combine a solvent having a boiling point of higher than 150° C. and 250° C. or lower with a solvent having a boiling point of 150° C. or lower under atmospheric pressure. Since the solvent having a boiling point of higher than 150° C. and 250° C. or lower is contained, the solvent vaporizes appropriately at the time of coating application and thus promotes the drying of the coating film so that coating unevenness can be inhibited and the film thickness uniformity can be improved. Furthermore, since the solvent having a boiling point of 150° C. or lower under atmospheric pressure is contained, it is possible to inhibit the solvent from remaining in the cured film described later. From the viewpoint of inhibiting the solvent from remaining in the cured film and improving the chemical resistance and adhesion for a long period of time, it is preferable to contain the solvent having a boiling point of 150° C. or lower under atmospheric pressure in an amount of 50 wt % or more of the entire solvent.

Examples of the solvent having a boiling point of 150° C. or lower under atmospheric pressure include ethanol, isopropyl alcohol, 1-propyl alcohol, 1-butanol, 2-butanol, isopentyl alcohol, ethylene glycol monomethyl ether, ethylene glycol dimethyl ether, ethylene glycol monoethyl ether, methoxymethyl acetate, propylene glycol monomethyl ether, propylene glycol monoethyl ether, propylene glycol monomethyl ether acetate, propylene glycol monopropyl ether, ethylene glycol monomethyl ether acetate, 1-methoxypropyl-2-acetate, acetol, acetylacetone, methyl isobutyl ketone, methyl ethyl ketone, methyl propyl ketone, methyl lactate, toluene, cyclopentanone, cyclohexane, n-heptane, benzene, methyl acetate, ethyl acetate, propyl acetate, isobutyl acetate, butyl acetate, isopentyl acetate, pentyl acetate, 3-hydroxy-3-methyl-2-butanone, 4-hydroxy-3-methyl-2-butanone, and 5-hydroxy-2-pentanone. Two or more of these compounds may be used.

Examples of the solvent having a boiling point of higher than 150° C. and 250° C. or lower under atmospheric pressure include ethylene glycol diethyl ether, ethylene glycol mono-n-butyl ether, ethylene glycol mono-tert-butyl ether, propylene glycol mono n-butyl ether, propylene glycol mono t-butyl ether, 2-ethoxyethyl acetate, 3-methoxy-1-butanol, 3-methoxy-3-methylbutanol, 3-methoxy-3-methylbutyl acetate, 3-methoxybutyl acetate, ethyl 3-ethoxypropionate, propylene glycol monomethyl ether propionate, dipropylene glycol methyl ether, diisobutyl ketone, diacetone alcohol, ethyl lactate, butyl lactate, dimethylformamide, dimethylacetamide, γ-butyrolactone, γ-valerolactone, δ-valerolactone, propylene carbonate, N-methylpyrrolidone, cyclohexanone, cycloheptanone, diethylene glycol monobutyl ether, and ethylene glycol dibutyl ether. Two or more of these compounds may be used.

The content of the solvent can be arbitrarily set according to a coating method or the like. For example, in forming a film by spin coating, in general, the content of the solvent is 50 wt % or more and 95 wt % or less of the amount of the photosensitive resin composition.

When the photosensitive resin composition contains a surfactant, the flowability during the application can be improved. Examples of the surfactant include fluorochemical surfactants such as “MEGAFACE” (registered trademark) F142D, F172, F173, F183, F445, F470, F475, and F477 (the above are trade names, manufactured by Dainippon Ink and Chemicals, Incorporated); fluorine surfactant such as NBX-15, and FTX-218 (the above are trade names, manufactured by NEOS COMPANY LIMITED); silicone surfactants such as “Disperbyk” (registered trademark) 333, 301, 331, 345, and 207 (the above are trade names, manufactured by BYK Japan KK); polyalkylene oxide surfactants; and poly(meth)acrylate surfactants. Two or more of these may be contained.

The solid content concentration of the photosensitive resin composition can be arbitrarily set depending on the coating method or the like. For example, in forming a film by spin coating as described later, in general, the solid content concentration is 5 wt % or more and 50 wt % or less.

Next, a method of producing the photosensitive resin composition will be described. The photosensitive resin composition can be obtained by mixing the above-described components (A) to (C) and, if necessary, other components. More specifically, for example, it is preferable to first disperse a mixed liquid of the siloxane resin (A), the particles (B) having a median diameter of 0.2 to 0.6 μm, and the organic solvent using a mill-type disperser filled with zirconia beads to obtain a pigment dispersion. On the other hand, it is preferable that the siloxane resin (A), the naphthoquinone diazide compound (C), and other additives as necessary are added to an arbitrary solvent and dissolved by stirring to obtain a diluent. Then, it is preferable that the pigment dispersion and the diluent are mixed, stirred, and then filtered.

In addition, since the photosensitive resin composition contains the particles (B) having excellent light diffusibility and a median diameter of 0.2 to 0.6 μm, the photosensitive resin composition is preferably used as a light diffusion layer forming material that diffuses light from a light emitting light source.

Next, the cured film will be described. The cured film includes the cured product of the photosensitive resin composition described above. The film thickness of the cured film is preferably 0.3 to 3.0 μm. When the film thickness of the cured film of the cured film is 0.3 μm or more, good light diffusibility can be exhibited. On the other hand, by setting the film thickness to 3.0 μm or less, light diffusion at the time of exposure can be suppressed, and good patternability can be realized. The haze of the cured film at a film thickness of 1.0 μm is preferably 20 to 98%. When the haze is 20% or more, good light diffusibility can be exhibited. On the other hand, by setting the haze to 98% or less, light diffusion at the time of exposure can be suppressed, and good patternability can be realized. The total light transmittance of the cured film with a thickness of 1.0 μm is preferably 40% to 90%. By setting the total light transmittance to 40% or more, it is possible to reduce the loss of light at the time of transmitting through the cured film and to secure sufficient brightness. On the other hand, by setting the total light transmittance to 90% or less, excessive transmission of light can be suppressed, and appropriate brightness can be realized. The cured film having the above characteristics can be obtained, for example, by performing pattern processing by a preferred production method described later using the photosensitive resin composition described above.

The cured film can be obtained, for example, by applying the above-described photosensitive resin composition in a film form, patterning the film as necessary, and then curing the film. It is preferable that the photosensitive resin composition is applied onto a base, prebaked, then exposed and developed to form a positive pattern, exposed again, and then thermally cured.

Examples of the method of applying the photosensitive resin composition on a base include microgravure coating, spin coating, dip coating, curtain flow coating, roll coating, spray coating and slit coating. Examples of a prebaking apparatus include a heater such as a hot plate and an oven. The prebaking temperature is preferably 50 to 130° C., and the prebaking time is preferably 30 seconds to 30 minutes. A film thickness after prebaking is preferably 0.1 to 15 μm.

The exposure may be performed through a desired mask or may be performed without a mask. Examples of the exposure apparatus include a stepper, a mirror projection mask aligner (MPA), and a parallel light mask aligner (PLA). The exposure intensity is preferably about 10 to 4,000 J/m² (in terms of an exposure amount at a wavelength of 365 nm). Examples of an exposure light source include ultraviolet light such as i-line, g-line, and h-line, KrF (wavelength: 248 nm) laser, and ArF (wavelength: 193 nm) laser.

Examples of the developing method include showering, dipping, and paddling. The time of immersion in the developer is preferably 5 seconds to 10 minutes. Examples of the developer include alkaline developers such as aqueous solutions containing inorganic alkalis such as hydroxides, carbonates, phosphates, silicates, and borates of alkali metals; amines such as 2-diethylaminoethanol, monoethanolamine, and diethanolamine; and quaternary ammonium salts such as tetramethylammonium hydroxide and choline. After development, the developed film is preferably rinsed with water and may then be dry-baked at a temperature in the range of 50 to 130° C.

As a method of re-exposure, it is preferable to expose the entire surface to light at about 100 to 20,000 J/m² (in terms of exposure amount at a wavelength of 365 nm) using an ultraviolet/visible exposure machine such as a stepper, a mirror projection mask aligner (MPA), and a parallel light mask aligner (PLA).

Examples of the heater used for thermal curing include a hot plate and an oven. The thermal curing temperature is preferably 80 to 230° C., and the thermal curing time is preferably about 15 minutes to 1 hour.

Next, a substrate with a cured film will be described, the substrate provided with a cured film patterned from the photosensitive resin material on a substrate, the cured film having a haze of 20 to 98% per film thickness of 1 μm.

The substrate with a cured film is provided with a cured film patterned on the substrate. The substrate has a function as a support in the substrate with a cured film. The cured film has a function of diffusing light from the light emitting light source. The haze of the patterned cured film per film thickness of 1 μm is preferably 20 to 98%. By setting the haze per film thickness of 1 μm to 20% or more, the light from the light emitting light source can be sufficiently diffused to make the luminance uniform. On the other hand, by setting the haze per film thickness of 1 μm to 98% or less, light diffusion at the time of exposure can be suppressed, and good patternability can be realized.

In the substrate with a cured film, the thickness of the cured film is preferably 0.3 to 3.0 μm. When the film thickness of the cured film is 0.3 μm or more, good light diffusibility can be exhibited. On the other hand, by setting the film thickness to 3.0 μm or less, light diffusion at the time of exposure can be suppressed, and good patternability can be realized.

Examples of the substrate in the substrate with a cured film include a glass substrate and a resin substrate plate containing polyimide. Since the glass substrate is excellent in transparency, it is suitably used as the substrate with our cured film. In addition, since the polyimide-containing resin substrate is excellent in bendability, it is suitably used for the substrate with a cured film.

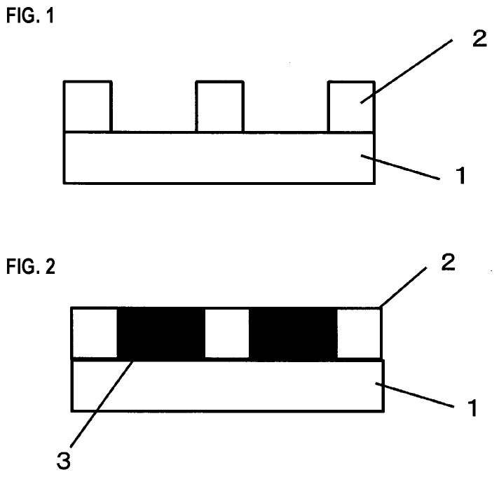

FIG. 1 is a cross-sectional view showing one aspect of the substrate with a cured film. A patterned cured film 2 is provided on a substrate 1.

The substrate with a cured film preferably includes a black layer between a piece of the patterned cured film and the adjacent piece of the cured film. By disposing the black layer between the adjacent cured films, the light shielding property can be improved to suppress light leakage from the light emitting light source in the display device.

FIG. 2 is a cross-sectional view showing one aspect of the substrate with a cured film including the black layer. A patterned cured film 2 is provided on the substrate 1, and a black layer 3 is provided between adjacent pieces of the cured film 2.

The black layer preferably has an optical density of 0.1 to 4.0 per film thickness of 1.0 μm. The film thickness of the black layer is preferably 0.5 to 10 μm as described later. Therefore, 1.0 μm is selected as a representative value of the film thickness of the black layer, and attention is paid to the optical density per film thickness of 1.0 μm. By setting the optical density per film thickness of 1.0 μm to 0.1 or more, the light shielding property can be further improved, and a clear image with higher contrast can be obtained. The optical density per film thickness of 1.0 μm is more preferably 0.5 or more. On the other hand, when the optical density per film thickness of 1.0 μm is 4.0 or less, patternability can be improved. The optical density per film thickness of 1.0 μm is more preferably 3.0 or less. The optical density (OD value) of the black layer can be determined by measuring the intensities of the incident light and the transmitted light using an optical densitometer (361T (visual); manufactured by X-Rite Inc.) and calculating the OD value from formula (7):

OD value=log10(I0/I) (7)

I0: Intensity of incident light

I: Intensity of transmitted light.

As a means of setting the optical density to the above range, for example, it is possible to cause the black layer to have a preferable composition described later.

The film thickness of the black layer is preferably 0.5 μm or more, more preferably 1.0 μm or more, from the viewpoint of improving the light shielding property. On the other hand, from the viewpoint of improving the flatness, the film thickness of the black layer is preferably 10 μm or less, more preferably 5 μm or less.

The black layer preferably contains a resin and a black pigment. The resin has a function of improving crack resistance and light resistance of the black layer. The black pigment has a function of absorbing incident light and reducing emitted light.

Examples of the resin include epoxy resins, (meth)acrylic polymers, polyurethanes, pol-yesters, polyimides, polyolefins, and polysiloxanes. Two or more of these may be contained. Among them, a polyimide is preferable because it is excellent in heat resistance and solvent resistance.

Examples of the black pigment include black organic pigments, mixed color organic pigments, and inorganic pigments. Examples of the black organic pigments include carbon black, perylene black aniline black, and benzofuranone-based pigments. These may be coated with a resin. Examples of the mixed color organic pigments include pigments produced by mixing two or more pigments of a color of red, blue, green, purple, yellow, magenta, and/or cyan to make a pseudo black color. Examples of the black inorganic pigments include graphite; fine particles of metals such as titanium, copper, iron, manganese, cobalt, chromium, nickel, zinc, calcium, and silver; metal oxides; metal composite oxides, metal sulfides, metal nitrides; metal oxynitrides; and metal carbides.

As a method of patterning the black layer on the substrate, for example, a method of patterning the black layer by a photosensitive paste method using a photosensitive material described in Japanese Patent Laid-open Publication No. 2015-1654 in the same manner as the above-described cured film is preferable.

Next, a display device will be described. The display device includes the substrate with a cured film and a light emitting light source. As the light emitting light source, a mini LED cell or a micro LED cell is preferable because of excellent light emission characteristics and reliability. The mini LED cell refers to a cell in which a large number of LED cells having vertical and horizontal lengths of 100 μm to 10 mm are arranged. The micro LED cell refers to a cell in which a large number of LED cells having vertical and horizontal lengths of less than 100 μm are arranged.

A method of manufacturing the display device will be described with reference to an example of a display device including the substrate with a cured film and a micro LED cell. After a driving wiring electrode is formed on the substrate, the micro LED cell is arranged. It can be produced by bonding the above-described substrate with a cured film and a micro LED cell with a sealant.

### EXAMPLES

Our compositions, films, display devices and methods will now be described in more detail with reference to examples, but the examples are not intended to limit this disclosure. Among the compounds used in synthesis examples and examples, details of those abbreviated are shown below:
PGMEA: propylene glycol monomethyl ether acetate
DAA: diacetone alcohol.

The solid content concentrations of a siloxane resin solution and an acrylic resin solution in Synthesis Examples 1 to 10 were determined by the following method. In an aluminum cup, 1.5 g of the siloxane resin solution or the acrylic resin solution was weighed and heated at 250° C. for 30 minutes using a hot plate to evaporate the liquid component. The weight of the solid content remaining in the aluminum cup after heating was weighed, and the solid content concentration of the siloxane resin solution or the acrylic resin solution was determined from the ratio to the weight before heating.

The weight average molecular weights of the siloxane resin and the acrylic resin solution in Synthesis Examples 1 to 10 were determined by the following method. With the use of a GPC analyzer (HLC-8220; manufactured by Tosoh Corporation), and with the use of tetrahydrofuran as a fluidized bed, GPC analysis was performed on the basis of “JIS K7252-3 (established date=Mar. 20, 2008)” to measure the weight average molecular weight in terms of polystyrene.

The content ratio of each organosilane unit in the siloxane resin in Synthesis Examples 1 to 9 was determined by the following method. A siloxane resin solution was injected into an NMR sample tube made of “Teflon” (registered trademark) having a diameter of 10 mm, ²⁹Si-NMR measurement was performed, and the content ratio of each organosilane unit was calculated from the ratio of the integral value of Si derived from a specific organosilane unit to the integral value of the entire Si derived from the organosilane. ²⁹Si-NMR measurement conditions are indicated below:
Apparatus: nuclear magnetic resonance apparatus (JNM-GX270; manufactured by JEOL Ltd.)
Measurement method: gated decoupling method
Measurement nucleus frequency: 53.6693 MHz (²⁹Si nucleus)
Spectrum width: 20,000 Hz
Pulse width: 12 ᵢus (45° pulse)
Pulse repetition time: 30.0 seconds
Solvent: acetone-d6
Reference matter: tetramethylsilane
Measurement temperature: 23° C.
Specimen rotation speed: 0.0 Hz.

### Synthesis Example 1 Siloxane Resin (A-1) Solution

In a 500-ml three-necked flask, 99.15 g (0.500 mol) of phenyltrimethoxysilane, 31.25 g (0.150 mol) of tetraethoxysilane, 21.82 g (0.100 mol) of trifluoropropyltrimethoxysilane, 24.64 g (0.100 mol) of 3-(3,4-epoxycyclohexyl)propyltrimethoxysilane, 20.43 g (0.150 mol) of methyltrimethoxysilane, and 127.47 g of PGMEA were charged. While the resulting mixture was stirred at room temperature, an aqueous phosphoric acid solution prepared by dissolving 0.863 g (0.50 wt % based on the charged monomers) of phosphoric acid in 56.70 g of water was added over 30 minutes. Thereafter, the three-necked flask was immersed in an oil bath at 70° C. for 90 minutes with stirring, and then the temperature of the oil bath was raised to 115° C. over 30 minutes. The internal temperature (solution temperature) of the three-necked flask reached 100° C. after 1 hour from the start of temperature increase, and then the mixture was heated and stirred for 2 hours (internal temperature was 100 to 110° C.) to obtain a siloxane resin solution. During the temperature increase and heating/stirring, 0.05 liters of nitrogen was divided. During the reaction, a total of 125.05 g of methanol and water as by-products were distilled out. PGMEA was added to the obtained siloxane resin solution so that the solid content concentration was 40 wt % to obtain a siloxane resin (A-1) solution. The weight average molecular weight of the obtained siloxane resin (A-1) was 3,500 (in terms of polystyrene). From the measurement results of ²⁹Si-NMR, in the siloxane resin (A-1), the molar ratios of the repeating units derived from phenyltrimethoxysilane, tetraethoxysilane, trifluoropropyltrimethoxysilane, 3-(3,4-epoxycyclohexyl)propyltrimethoxysilane, and methyltrimethoxysilane were 50 mol %, 15 mol %, 10 mol %, 10 mol %, and 15 mol %, respectively.

### Synthesis Example 2 Siloxane Resin (A-2) Solution

In a 500-ml three-necked flask, 99.15 g (0.500 mol) of phenyltrimethoxysilane, 31.25 g (0.150 mol) of tetraethoxysilane, 24.64 g (0.100 mol) of 3-(3,4-epoxycyclohexyl)propyltrimethoxysilane, 34.05 g (0.250 mol) of methyltrimethoxysilane, and 112.44 g of PGMEA were charged. While the resulting mixture was stirred at room temperature, an aqueous phosphoric acid solution prepared by dissolving 0.822 g (0.50 wt % based on the charged monomers) of phosphoric acid in 56.70 g of water was added over 30 minutes. Thereafter, the three-necked flask was immersed in an oil bath at 70° C. for 90 minutes with stirring, and then the temperature of the oil bath was raised to 115° C. over 30 minutes. The internal temperature (solution temperature) of the three-necked flask reached 100° C. after 1 hour from the start of temperature increase, and then the mixture was heated and stirred for 2 hours (internal temperature was 100 to 110° C.) to obtain a siloxane resin solution. During the temperature increase and heating/stirring, 0.05 liters of nitrogen was divided. During the reaction, a total of 129.15 g of methanol and water as by-products were distilled out. PGMEA was added to the obtained siloxane resin solution so that the solid content concentration was 40 wt % to obtain a siloxane resin (A-2) solution. The weight average molecular weight of the obtained siloxane resin (A-2) was 4,100 (in terms of polystyrene). From the measurement results of ²⁹Si-NMR, in the siloxane resin (A-2), the molar ratios of the repeating units derived from phenyltrimethoxysilane, tetraethoxysilane, 3-(3,4-epoxycyclohexyl)propyltrimethoxysilane, and methyltrimethoxysilane were 50 mol %, 15 mol %, 10 mol %, and 25 mol %, respectively.

### Synthesis Example 3 Siloxane Resin (A-3) Solution

In a 500-ml three-necked flask, 99.15 g (0.500 mol) of phenyltrimethoxysilane, 24.64 g (0.100 mol) of 3-(3,4-epoxycyclohexyl)propyltrimethoxysilane, 54.48 g (0.400 mol) of methyltrimethoxysilane, and 103.44 g of PGMEA were charged. While the resulting mixture was stirred at room temperature, an aqueous phosphoric acid solution prepared by dissolving 0.768 g (0.50 wt % based on the charged monomers) of phosphoric acid in 54.00 g of water was added over 30 minutes. Thereafter, the three-necked flask was immersed in an oil bath at 70° C. for 90 minutes with stirring, and then the temperature of the oil bath was raised to 115° C. over 30 minutes. The internal temperature (solution temperature) of the three-necked flask reached 100° C. after 1 hour from the start of temperature increase, and then the mixture was heated and stirred for 2 hours (internal temperature was 100 to 110° C.) to obtain a siloxane resin solution. During the temperature increase and heating/stirring, 0.05 liters of nitrogen was divided. During the reaction, a total of 123.00 g of methanol and water as by-products were distilled out. PGMEA was added to the obtained siloxane resin solution so that the solid content concentration was 40 wt % to obtain a siloxane resin (A-3) solution. The weight average molecular weight of the obtained siloxane resin (A-3) was 4,100 (in terms of polystyrene). From the measurement results of ²⁹Si-NMR, in the siloxane resin (A-3), the molar ratios of the repeating units derived from phenyltrimethoxysilane, 3-(3,4-epoxycyclohexyl)propyltrimethoxysilane, and methyltrimethoxysilane were 50 mol %, 10 mol %, and 40 mol %, respectively.

### Synthesis Example 4 Siloxane Resin (A-4) Solution

In a 500-ml three-necked flask, 59.49 g (0.300 mol) of phenyltrimethoxysilane, 31.25 g (0.150 mol) of tetraethoxysilane, 21.82 g (0.100 mol) of trifluoropropyltrimethoxysilane, 24.64 g (0.100 mol) of 3-(3,4-epoxycyclohexyl)propyltrimethoxysilane, 47.64 g (0.350 mol) of methyltrimethoxysilane, and 112.29 g of PGMEA were charged. While the resulting mixture was stirred at room temperature, an aqueous phosphoric acid solution prepared by dissolving 0.801 g (0.50 wt % based on the charged monomers) of phosphoric acid in 56.70 g of water was added over 30 minutes. Thereafter, the three-necked flask was immersed in an oil bath at 70° C. for 90 minutes with stirring, and then the temperature of the oil bath was raised to 115° C. over 30 minutes. The internal temperature (solution temperature) of the three-necked flask reached 100° C. after 1 hour from the start of temperature increase, and then the mixture was heated and stirred for 2 hours (internal temperature was 100 to 110° C.) to obtain a siloxane resin solution. During the temperature increase and heating/stirring, 0.05 liters of nitrogen was divided. During the reaction, a total of 125.05 g of methanol and water as by-products were distilled out. PGMEA was added to the obtained siloxane resin solution so that the solid content concentration was 40 wt % to obtain a siloxane resin (A-4) solution. The weight average molecular weight of the obtained siloxane resin (A-4) was 4,600 (in terms of polystyrene). From the measurement results of ²⁹Si-NMR, in the siloxane resin (A-4), the molar ratios of the repeating units derived from phenyltrimethoxysilane, tetraethoxysilane, trifluoropropyltrimethoxysilane, 3-(3,4-epoxycyclohexyl)propyltrimethoxysilane, and methyltrimethoxysilane were 30 mol %, 15 mol %, 10 mol %, 10 mol %, and 35 mol %, respectively.

### Synthesis Example 5 Siloxane Resin (A-5) Solution

In a 500-ml necked flask, 59.49 g (0.300 mol) of phenyltrimethoxysilane, 62.49 g (0.300 mol) of tetraethoxysilane, 21.82 g (0.100 mol) of trifluoropropyltrimethoxysilane, 24.64 g (0.100 mol) of 3-(3,4-epoxycyclohexyl)propyltrimethoxysilane, 27.24 g (0.200 mol) of methyltrimethoxysilane, and 121.29 g of PGMEA were charged. While the resulting mixture was stirred at room temperature, an aqueous phosphoric acid solution prepared by dissolving 0.855 g (0.50 wt % based on the charged monomers) of phosphoric acid in 59.40 g of water was added over 30 minutes. Thereafter, the three-necked flask was immersed in an oil bath at 70° C. for 90 minutes with stirring, and then the temperature of the oil bath was raised to 115° C. over 30 minutes. The internal temperature (solution temperature) of the three-necked flask reached 100° C. after 1 hour from the start of temperature increase, and then the mixture was heated and stirred for 2 hours (internal temperature was 100 to 110° C.) to obtain a siloxane resin solution. During the temperature increase and heating/stirring, 0.05 liters of nitrogen was divided. During the reaction, a total of 131.20 g of methanol and water as by-products were distilled out. PGMEA was added to the obtained siloxane resin solution so that the solid content concentration was 40 wt % to obtain a siloxane resin (A-5) solution. The weight average molecular weight of the obtained siloxane resin (A-5) was 3,900 (in terms of polystyrene). From the measurement results of ²⁹Si-NMR, in the siloxane resin (A-5), the molar ratios of the repeating units derived from phenyltrimethoxysilane, tetraethoxysilane, trifluoropropyltrimethoxysilane, 3-(3,4-epoxycyclohexyl)propyltrimethoxysilane, and methyltrimethoxysilane were 30 mol %, 30 mol %, 10 mol %, 10 mol %, and 20 mol %, respectively.

### Synthesis Example 6 Siloxane Resin (A-6) Solution

In a 500-ml three-necked flask, 59.49 g (0.300 mol) of phenyltrimethoxysilane, 31.25 g (0.150 mol) of tetraethoxysilane, 65.46 g (0.300 mol) of trifluoropropyltrimethoxysilane, 24.64 g (0.100 mol) of 3-(3,4-epoxycyclohexyl)propyltrimethoxysilane, 20.43 g (0.150 mol) of methyltrimethoxysilane, and 142.36 g of PGMEA were charged. While the resulting mixture was stirred at room temperature, an aqueous phosphoric acid solution prepared by dissolving 0.883 g (0.50 wt % based on the charged monomers) of phosphoric acid in 56.70 g of water was added over 30 minutes. Thereafter, the three-necked flask was immersed in an oil bath at 70° C. for 90 minutes with stirring, and then the temperature of the oil bath was raised to 115° C. over 30 minutes. The internal temperature (solution temperature) of the three-necked flask reached 100° C. after 1 hour from the start of temperature increase, and then the mixture was heated and stirred for 2 hours (internal temperature was 100 to 110° C.) to obtain a siloxane resin solution. During the temperature increase and heating/stirring, 0.05 liters of nitrogen was divided. During the reaction, a total of 116 g of methanol and water as by-products were distilled out. PGMEA was added to the obtained siloxane resin solution so that the solid content concentration was 40 wt % to obtain a siloxane resin (A-6) solution. The weight average molecular weight of the obtained siloxane resin (A-6) was 3,100 (in terms of polystyrene). From the measurement results of ²⁹Si-NMR, in the siloxane resin (A-6), the molar ratios of the repeating units derived from phenyltrimethoxysilane, tetraethoxysilane, trifluoropropyltrimethoxysilane, 3-(3,4-epoxycyclohexyl)propyltrimethoxysilane, and methyltrimethoxysilane were 30 mol %, 15 mol %, 30 mol %, 10 mol %, and 15 mol %, respectively.

### Synthesis Example 7 Siloxane Resin (A-7) Solution

In a 500-ml three-necked flask, 128.90 g (0.650 mol) of phenyltrimethoxysilane, 31.25 g (0.150 mol) of tetraethoxysilane, 21.82 g (0.100 mol) of trifluoropropyltrimethoxysilane, 12.32 g (0.050 mol) of 3-(3,4-epoxycyclohexyl)propyltrimethoxysilane, 6.81 g (0.050 mol) of methyltrimethoxysilane, and 147.18 g of PGMEA were charged. While the resulting mixture was stirred at room temperature, an aqueous phosphoric acid solution prepared by dissolving 0.944 g (0.50 wt % based on the charged monomers) of phosphoric acid in 56.70 g of water was added over 30 minutes. Thereafter, the three-necked flask was immersed in an oil bath at 70° C. for 90 minutes with stirring, and then the temperature of the oil bath was raised to 115° C. over 30 minutes. The internal temperature (solution temperature) of the three-necked flask reached 100° C. after 1 hour from the start of temperature increase, and then the mixture was heated and stirred for 2 hours (internal temperature was 100 to 110° C.) to obtain a siloxane resin solution. During the temperature increase and heating/stirring, 0.05 liters of nitrogen was divided. During the reaction, a total of 125.05 g of methanol and water as by-products were distilled out. PGMEA was added to the obtained siloxane resin solution so that the solid content concentration was 40 wt % to obtain a siloxane resin (A-7) solution. The weight average molecular weight of the obtained siloxane resin (A-7) was 3,100 (in terms of polystyrene). From the measurement results of ²⁹Si-NMR, in the siloxane resin (A-7), the molar ratios of the repeating units derived from phenyltrimethoxysilane, tetraethoxysilane, trifluoropropyltrimethoxysilane, 3-(3,4-epoxycyclohexyl)propyltrimethoxysilane, and methyltrimethoxysilane were 65 mol %, 15 mol %, 10 mol %, 5 mol %, and 5 mol %, respectively.

### Synthesis Example 8 Siloxane Resin (A-8) Solution

In a 500-ml three-necked flask, 31.25 g (0.150 mol) of tetraethoxysilane, 24.64 g (0.100 mol) of 3-(3,4-epoxycyclohexyl)propyltrimethoxysilane, 102.15 g (0.750 mol) of methyltrimethoxysilane, and 74.49 g of PGMEA were charged. While the resulting mixture was stirred at room temperature, an aqueous phosphoric acid solution prepared by dissolving 0.667 g (0.50 wt % based on the charged monomers) of phosphoric acid in 56.70 g of water was added over 30 minutes. Thereafter, the three-necked flask was immersed in an oil bath at 70° C. for 90 minutes with stirring, and then the temperature of the oil bath was raised to 115° C. over 30 minutes. The internal temperature (solution temperature) of the three-necked flask reached 100° C. after 1 hour from the start of temperature increase, and then the mixture was heated and stirred for 2 hours (internal temperature was 100 to 110° C.) to obtain a siloxane resin solution. During the temperature increase and heating/stirring, 0.05 liters of nitrogen was divided. During the reaction, a total of 129.15 g of methanol and water as by-products were distilled out. PGMEA was added to the obtained siloxane resin solution so that the solid content concentration was 40 wt % to obtain a siloxane resin (A-8) solution. The weight average molecular weight of the obtained siloxane resin (A-8) was 5,100 (in terms of polystyrene). From the measurement results of ²⁹Si-NMR, in the siloxane resin (A-8), the molar ratios of the repeating units derived from tetraethoxysilane, 3-(3,4-epoxycyclohexyl)propyltrimethoxysilane, and methyltrimethoxysilane were 15 mol %, 10 mol %, and 75 mol %, respectively.

### Synthesis Example 9 Siloxane Resin (A-9) Solution

In a 500-ml three-necked flask, 21.82 g (0.100 mol) of trifluoropropyltrimethoxysilane, 24.64 g (0.100 mol) of 3-(3,4-epoxycyclohexyl)propyltrimethoxysilane, 108.96 g (0.800 mol) of methyltrimethoxysilane, and 80.52 g of PGMEA were charged. While the resulting mixture was stirred at room temperature, an aqueous phosphoric acid solution prepared by dissolving 0.654 g (0.50 wt % based on the charged monomers) of phosphoric acid in 54.00 g of water was added over 30 minutes. Thereafter, the three-necked flask was immersed in an oil bath at 70° C. for 90 minutes with stirring, and then the temperature of the oil bath was raised to 115° C. over 30 minutes. The internal temperature (solution temperature) of the three-necked flask reached 100° C. after 1 hour from the start of temperature increase, and then the mixture was heated and stirred for 2 hours (internal temperature was 100 to 110° C.) to obtain a siloxane resin solution. During the temperature increase and heating/stirring, 0.05 liters of nitrogen was divided. During the reaction, a total of 118.90 g of methanol and water as by-products were distilled out. PGMEA was added to the obtained siloxane resin solution so that the solid content concentration was 40 wt % to obtain a siloxane resin (A-9) solution. The weight average molecular weight of the obtained siloxane resin (A-9) was 5,100 (in terms of polystyrene). From the measurement results of ²⁹Si-NMR, in the siloxane resin (A-9), the molar ratios of the repeating units derived from trifluoropropyltrimethoxysilane, 3-(3,4-epoxycyclohexyl)propyltrimethoxysilane, and methyltrimethoxysilane were 10 mol %, 10 mol %, and 80 mol %, respectively.

Tables 1 and 2 show the raw material compositions of the siloxane resins of Synthesis Examples 1 to 9.

TABLE 1

| | | Raw material (mol %) | | | |
|---|---|---|---|---|---|
| | | General formula (1) | General formula (2) | General formula (3) | Others |
| Synthesis | Siloxane | Phenyltrimethoxysilane | Tetraethoxysilane | Trifluoropropyltrimethoxysilane | 3-(3,4-Epoxycyclohexyl)propyl- |
| Example 1 | resin | (50) | (15) | (10) | trimethoxysilane |
| | solution | | | | (10) |
| | (A-1) | | | | Methyltrimethoxysilane (15) |
| Synthesis | Siloxane | Phenyltrimethoxysilane | Tetraethoxysilane | — | 3-(3,4-Epoxycyclohexyl)propyl- |
| Example 2 | resin | (50) | (15) | | trimethoxysilane |
| | solution | | | | (10) |
| | (A-2) | | | | Methyltrimethoxysilane (25) |
| Synthesis | Siloxane | Phenyltrimethoxysilane | — | — | 3-(3,4-Epoxycyclohexyl)propyl- |
| Example 3 | resin | (50) | | | trimethoxysilane |
| | solution | | | | (10) |
| | (A-3) | | | | Methyltrimethoxysilane (40) |
| Synthesis | Siloxane | Phenyltrimethoxysilane | Tetraethoxysilane | Trifluoropropyltrimethoxysilane | 3 -(3,4-Epoxycyclohexyl)propyl- |
| Example 4 | resin | (30) | (15) | (10) | trimethoxysilane |
| | solution | | | | (10) |
| | (A-4) | | | | Methyltrimethoxysilane (35) |

TABLE 2

| | | Raw material (mol %) | | | |
|---|---|---|---|---|---|
| | | General formula (1) | General formula (2) | General formula (3) | Others |
| Synthesis | Siloxane | Phenyltrimethoxysilane | Tetraethoxysilane | Trifluoropropyltrimethoxysilane | 3-(3,4-Epoxycyclohexyl)propyl- |
| Example 5 | resin | (30) | (30) | (10) | trimethoxysilane |
| | solution | | | | (10) |
| | (A-5) | | | | Methyltrimethoxysilane (20) |
| Synthesis | Siloxane | Phenyltrimethoxysilane | Tetraethoxysilane | Trifluoropropyltrimethoxysilane | 3-(3,4-Epoxycyclohexyl)propyl- |
| Example 6 | resin | (30) | (15) | (30) | trimethoxysilane |
| | solution | | | | (10) |
| | (A-6) | | | | Methyltrimethoxysilane (15) |
| Synthesis | Siloxane | Phenyltrimethoxysilane | Tetraethoxysilane | Trifluoropropyltrimethoxysilane | 3-(3,4-Epoxycyclohexyl)propyl- |
| Example 7 | resin | (65) | (15) | (10) | trimethoxysilane |
| | solution | | | | (5) |
| | (A-7) | | | | Methyltrimethoxysilane (5) |
| Synthesis | Siloxane | — | Tetraethoxysilane | — | 3-(3,4-Epoxycyclohexyl)propyl- |
| Example 8 | resin | | (15) | | trimethoxysilane |
| | solution | | | | (10) |
| | (A-8) | | | | Methyltrimethoxysilane (75) |
| Synthesis | Siloxane | — | — | Trifluoropropyltrimethoxysilane | 3-(3,4-Epoxycyclohexyl)propyl- |
| Example 9 | resin | | | (10) | trimethoxysilane |
| | solution | | | | (10) |
| | (A-9) | | | | Methyltrimethoxysilane (80) |

### Synthesis Example 10 Acrylic Resin (a) Solution

In a 500-ml three-necked flask, 3 g of 2,2′-azobis(isobutyronitrile) and 50 g of PGMEA were charged. Then, 30 g of methacrylic acid, 35 g of benzyl methacrylate, and 35 g of tricyclo[5.2.1.0^{2,6}]decane-8-yl methacrylate were charged thereinto and stirred for a while at room temperature. The inside of the flask was purged with nitrogen, and the contents were heated and stirred at 70° C. for 5 hours to provide an acrylic resin solution. PGMEA was added to the obtained acrylic resin solution so that the solid content concentration was 40 wt % to obtain an acrylic resin (a) solution. The weight average molecular weight of the acrylic resin (a) was 10,000 (in terms of polystyrene).

### (1) Patternability

The photosensitive resin composition obtained in each of the Examples and Comparative Examples was spin-coated on a glass substrate (an “ITO substrate”) whose surface was sputtered with ITO using a spin coater (trade name: 1H-360S, manufactured by Mikasa Co., Ltd.), and the substrate was prebaked on a hot plate (trade name: SCW-636, manufactured by Dainippon Screen Mfg. Co., Ltd.) at 100° C. for 2 minutes to produce a film having a thickness of 1.0 μm.

The produced film was subjected to contact exposure using a parallel light mask aligner (trade name: PLA-501F, manufactured by Canon Inc.) through a gray scale mask having each of line-and-space patterns having widths of 50 μm, 40 μm, 30 μm, 20 μm, 15 μm, 10 μm, 7 μm, 5 μm, and 4μm using an ultra-high-pressure mercury lamp as a light source. Thereafter, the film was shower-developed with a 2.38 wt % aqueous tetramethylammonium hydroxide (“TMAH”) solution (trade name: ELM-D, manufactured by MITSUBISHI GAS CHEMICAL CO., INC.) for 120 seconds using an automatic developing apparatus (“AD-2000 (trade name)” manufactured by Takizawa Sangyo Co., Ltd.) and then rinsed with water for 30 seconds. Thereafter, as bleaching exposure, exposure was performed at an exposure amount of 1,000 mJ/cm² (in terms of i-line) using a parallel light mask aligner (trade name: PLA-501F, manufactured by Canon Inc.), and the film was cured in an oven (IHPS-222; manufactured by Espec Corp.) at 170° C. for 30 minutes in the air to prepare a cured film. After exposure and development, the exposure amount at which line-and-space patterns with a width of 20 μm were formed at a width ratio of 1:1 was taken as the selected exposure amount, the minimum pattern dimension after the development at the selected exposure amount was taken as the resolution after development, and he minimum pattern dimension after the curing was taken as the resolution after curing.

In addition, the pattern after development was observed visually and with a microscope with a magnification adjusted to 50 to 100 times, and the development residue was evaluated according to the following criteria based on the degree of the unexposed portion remaining undissolved.

5: No residue was visually observed, and no residue was observed even in a fine pattern of 10 μm or less in microscopic observation.

4: No residue was visually observed, and in microscopic observation, no residue was observed in a pattern of more than 10 μm, but a residue was observed in a pattern of 10 μm or less.

3: No residue was visually observed, but a residue was observed in a pattern of more than 10 μm in microscopic observation.

2: A residue is visually observed at the substrate end portion (thick film portion).

1: A residue is visually observed in the entire unexposed portion.

### (2) Total Light Transmittance and Haze

The photosensitive resin composition obtained in each of the Examples and Comparative Examples was spin-coated on a 10 cm square alkali-free glass substrate using a spin coater (trade name: 1H-360S, manufactured by Mikasa Co., Ltd.) so that the film thickness after curing was 1.0 μm and prebaked at a temperature of 100° C. for 2 minutes using a hot plate (SCW-636) to form a prebaked film. The produced prebaked film was subjected to development, rinsing, bleaching exposure, and curing in the same manner as in the evaluation method of “Patternability” in (1) described above except that exposure through a mask was not performed. The total light transmittance and the haze of the obtained cured film were measured according to JIS “K7361 (established date=Jan. 20, 1997)” using NDH-2000 manufactured by Nippon Denshoku Industries Co., Ltd.

### (3) Evaluation of Heat Resistance

The photosensitive resin composition obtained in each of the Examples and Comparative Examples was applied onto a 10 cm square alkali-free glass substrate using a spin coater (1H-360S; manufactured by Mikasa Co., Ltd.) so that the film thickness after curing was 1.0 μm, and a cured film was produced in the same manner as in the evaluation method of “Total Light Transmittance and Haze” described above.

For the resulting alkali-free glass substrate with a cured film, the total light transmittance and haze were measured in the same manner as in the “Total Light Transmittance and Haze” evaluation method described above, and the measured values were taken as values before additional curing. Further, additional curing was performed at a temperature of 240° C. for 2 hours in the air using an oven (IHPS-222), then the total light transmittance and the haze were measured in the same manner, and the measured values were defined as values after the additional curing. The absolute values of the numerical values obtained by subtracting the values before the additional curing from the values after the additional curing were evaluated as change widths, and the smaller the change widths, the better the heat resistance. The change width of the total light transmittance is preferably 3.0 or less, more preferably 2.0 or less. The change width of the haze is preferably 1.0 or less, more preferably 0.5 or less.

### (4) Evaluation of Light Resistance

The photosensitive resin composition obtained in each of the Examples and Comparative Examples was applied onto a 10 cm square alkali-free glass substrate using a spin coater (1H-360S; manufactured by Mikasa Co., Ltd.) so that the film thickness after curing was 1.0 μm, and a cured film was produced in the same manner as in the evaluation method of “Total Light Transmittance and Haze” described above.

For the resulting alkali-free glass substrate with a cured film, the total light transmittance and haze were measured in the same manner as in the “Total Light Transmittance and Haze” evaluation method described above, and the measured values were taken as values before irradiation with ultraviolet light. Further, after irradiation with ultraviolet light having a wavelength of 365 nm and an illuminance of 0.6 mW/cm² in the air at a temperature of 40° C. for 100 hours, the total light transmittance and the haze were measured in the same manner, and the measured values were defined as values after the irradiation with ultraviolet light. The absolute values of the numerical values obtained by subtracting the values after the irradiation with ultraviolet light from the values before the irradiation with ultraviolet light were evaluated as change widths, and the smaller the change widths, the better the light resistance. The change width of the total light transmittance is preferably 0.8 or less, more preferably 0.5 or less. The change width of the haze is preferably 0.4 or less, more preferably 0.2 or less.

### (5) Evaluation of Bendability

A cured film having a film thickness of 1.0 μm was formed on a polyimide film (“Kapton” (registered trademark) EN-100 (trade name), manufactured by Toray Industries, Inc.) in the same manner as in the evaluation method of “Total Light Transmittance and Haze” described above using the photosensitive resin composition obtained in each of the Examples and Comparative Examples. Then, 10 polyimide film substrates each provided with a cured film were cut into a size of 50 mm in length×10 mm in width. Next, with the cured film surface outward, the polyimide film substrate was held for 30 seconds while the substrate was bent at 180° on a 25 mm vertical line. The folded polyimide film substrate was opened, the bent part on the 25 mm vertical line of the cured film surface was observed with the use of an FPD inspection microscope (MX-61L; manufactured by Olympus Corporation), and the appearance change of the cured film surface was evaluated. The bending test was performed within a range of a curvature radius of 0.1 to 1.0 mm, and the minimum curvature radius at which peeling of the cured film from the polyimide film substrate and a change in appearance such as cracks on the surface of the cured film did not occur was recorded.

### (6) Storage Stability

The viscosity (viscosity before storage) of the photosensitive resin composition obtained in each of the Examples and Comparative Examples was measured after the preparation was completed. In addition, the photosensitive resin composition obtained in each of the Examples and Comparative Examples was placed in a sealed container, and the viscosity after storage at 23° C. for 7 days was measured in the same manner. The storage stability was evaluated from the viscosity change rate ({|viscosity after storage−viscosity before storage|/viscosity before storage}×100) according to the following criteria:

A: Viscosity change rate of less than 5%

B: Viscosity change rate of 5% or more and less than 10%.

### Example 1

A particle dispersion (MW-1) was obtained by performing dispersing using a milltype disperser loaded with zirconia beads with 50.00 g of titanium dioxide (R-960; manufactured by Du Pont Co. (SiO₂/Al₂O₃ surface treatment, median diameter: 0.21 μm)) as the particles (B) having a median diameter of 0.2 to 0.6 μm and 50.00 g of the siloxane resin (A-1) solution obtained in Synthesis Example 1 as the siloxane resin (A).

Next, 5.00 g of the particle dispersion (MW-1), 12.338 g of the siloxane resin (A-1) solution, 1.000 g of TP5-280M (manufactured by Toyo Gosei Co., Ltd.) as the (C) naphthoquinonezide compound, 0.150 g of CGI-MDT (manufactured by Hereus K.K.) as the curing agent, 0.200 g of a melamine resin compound (“NIKALAC” (registered trademark) MX-270 (trade name) manufactured by SanwaKasei Co., Ltd.), 0.200 g of 3-glycidoxypropylmethyldimethoxysilane (KBM-303 (trade name), manufactured by Shin-Etsu Chemical Co., Ltd.) as the adhesion improver, and 1.500 g (corresponding to a concentration of 300 ppm) of a 1 wt % PGMEA diluted solution of a fluorine-based surfactant (“MEGAFACE” (registered trademark) F-477 (trade name), manufactured by DIC Corporation) as the surfactant were dissolved in a mixed solvent of 8.000 g of DAA and 21.613 g of PGMEA, and the resulting solution was stirred. Then, the mixture was filtered with a 5.0 μm filter to give a photosensitive resin composition (P-1). The obtained photosensitive resin composition (P-1) was evaluated for the patternability, total light transmittance, haze, heat resistance, light resistance, bendability, and storage stability by the above-described methods.

### Examples 2 to 6

Photosensitive resin compositions (P-2) to (P-6) were obtained in the same manner as in Example 1 except that the siloxane resin (A-2) to (A-6) solutions were respectively used instead of the siloxane resin (A-1) solution. The obtained photosensitive resin compositions (P-2) to (P-6) were evaluated in the same manner as in Example 1.

### Example 7

A photosensitive resin composition (P-7) was obtained in the same manner as in Example 1 except that the addition amount of the particle dispersion (MW-1) was changed to 10.00 g, the addition amount of the siloxane resin (A-1) solution was changed to 3.588 g, and a mixed solvent of 8.000 g of DAA and 25.363 g of PGMEA was used. The obtained photosensitive resin composition (P-7) was evaluated in the same manner as in Example 1.

### Example 8

A photosensitive resin composition (P-8) was obtained in the same manner as in Example 1 except that the addition amount of the particle dispersion (MW-1) was changed to 1.000 g, the addition amount of the siloxane resin (A-1) solution was changed to 19.338 g, and a mixed solvent of 8.000 g of DAA and 18.613 g of PGMEA was used. The obtained photosensitive resin composition (P-8) was evaluated in the same manner as in Example 1.

### Example 9

A photosensitive resin composition (P-9) was obtained in the same manner as in Example 1 except that titanium dioxide (CR-97; manufactured by ISHIHARA SANGYO KAISHA, LTD. (Al₂O₃/ZrO₂ surface treatment, median diameter: 0.25 μm)) was used instead of R-960 as the particles (B) having a median diameter of 0.2 to 0.6 μm. The obtained photosensitive resin composition (P-9) was evaluated in the same manner as in Example 1.

### Example 10

A photosensitive resin composition (P-10) was obtained in the same manner as in Example 1 except that zirconia oxide (3YI-R; manufactured by Toray Industries, Inc. (Al₂O₃ surface treatment, median system: 0.50 μm)) was used instead of R-960 as the particles (B) having a median diameter of 0.2 to 0.6 μm. The obtained photosensitive resin composition (P-10) was evaluated in the same manner as in Example 1.

### Example 11

A photosensitive resin composition (P-11) was obtained in the same manner as in Example 1 except that aluminum oxide (AO-502; manufactured by Admatechs Co., Ltd. (no surface treatment, median diameter: 0.25 μm)) was used instead of R-960 as the particles (B) having a median diameter of 0.2 to 0.6 μm. The obtained photosensitive resin composition (P-11) was evaluated in the same manner as in Example 1.

### Example 12

A photosensitive resin composition (P-12) was obtained in the same manner as in Example 1 except that the addition amount of the siloxane resin (A-1) solution was changed to 13.588 g, the addition amount of the naphthoquinone diazide compound (C) TP5-280M was changed to 0.500 g, and a mixed solvent of 8.000 g of DAA and 20.863 g of PGMEA was used. The obtained photosensitive resin composition (P-12) was evaluated in the same manner as in Example 1.

### Example 13

A photosensitive resin composition (P-13) was obtained in the same manner as in Example 1 except that the addition amount of the siloxane resin (A-1) solution was changed to 11.088 g, the addition amount of the naphthoquinone diazide compound (C) TP5-280M was changed to 1.500 g, and a mixed solvent of 8.000 g of DAA and 22.363 g of PGMEA was used. The obtained photosensitive resin composition (P-13) was evaluated in the same manner as in Example 1.

### Comparative Examples 1 to 3

Photosensitive resin compositions (P-14) to (P-16) were obtained in the same manner as in Example 1 except that the siloxane resin (A-7) to (A-9) solutions were respectively used instead of the siloxane resin (A-1) solution. The obtained photosensitive resin compositions (P-14) to (P-16) were evaluated in the same manner as in Example 1.

### Comparative Example 4

A photosensitive resin composition (P-17) was obtained in the same manner as in Example 1 except that the acrylic resin solution (a) was used instead of the siloxane resin (A-1) solution. The obtained photosensitive resin composition (P-17) was evaluated in the same manner as in Example 1.

### Comparative Example 5

Instead of the particles (B) having a median diameter of 0.2 to 0.6 μm, “OPTOLAKE TR-550” (trade name, manufactured by Catalysts and Chemicals Industries Co., Ltd., composition: 20 wt % of titanium dioxide particles and 80 wt % of methanol) was used as a dispersion of titanium dioxide particles. The titanium dioxide particles “OPTOLAKE TR-550” were surface-treated with SiO₂/Al₂O₃ and had a median diameter of 0.015 μm. A photosensitive resin composition (P-18) was obtained in the same manner as in Example 1 except that 12.50 g of OPTOLAKE TR-550 was added instead of the particle dispersion (MW-1), the addition amount of the siloxane resin (A-1) solution was changed to 13.588 g, and a mixed solvent of 8.000 g of DAA and 12.363 g of PGMEA was used. The obtained photosensitive resin composition (P-18) was evaluated in the same manner as in Example 1.

### Comparative Example 6

A photosensitive resin composition (P-19) was obtained in the same manner as in Example 1 except that the particle dispersion (MW-1) was not used, the addition amount of the siloxane resin (A-1) solution was changed to 21.088 g, and a mixed solvent of 8.000 g of DAA and 17.863 g of PGMEA was used. The obtained photosensitive resin composition (P-19) was evaluated in the same manner as in Example 1.

### Comparative Example 7

A photosensitive resin composition (P-20) was obtained in the same manner as in Example 1 except that TP5-280M is not used as the naphthoquinonezide compound (C), the addition amount of the siloxane resin (A-1) solution was changed to 14.838 g, and a mixed solvent of 8.000 g of DAA and 20.113 g of PGMEA was used. The obtained photosensitive resin composition (P-20) was evaluated in the same manner as in Example 1.

Compositions in Examples 1 to 13 and Comparative Examples 1 to 7 are shown in Tables 3 and 4, and evaluation results are shown in Tables 5 and 6.

TABLE 3

| | Photosen- | | | | | | | | | |
|---|---|---|---|---|---|---|---|---|---|---|
| | sitive | Siloxane | Particles (B) | Naphtho- | | | | | | |
| | light- | resin/ | having median | quinone | | | | Other additives (wt %) | | |
| | diffusing | acrylic | diameter of | diazide | | | | | Adhesion | |
| | resin | resin (A) | 0.2 to 0.6 μm | compound (C) | | | | Curing | improving | |
| | composition | (wt %) | (wt %) | (wt %) | Organic solvent (wt %) | | | agent | agent | Surfactant |
| Example 1 | P-1 | A- | R- | TP5- | PGMEA(64) | DAA(16) | — | CGI-MDT(0.3) | KBM- | F- |
| | | 1(11.87) | 960(5) | 280M(2) | | | | MX-270(0.4) | 303(0.4) | 477(300 ppm) |
| Example 2 | P-2 | A- | R- | TP5- | PGMEA(64) | DAA(16) | — | CGI-MDT(0.3) | KBM- | F- |
| | | 2(11.87) | 960(5) | 280M(2) | | | | MX-270(0.4) | 303(0.4) | 477(300 ppm) |
| Example 3 | P-3 | A- | R- | TP5- | PGMEA(64) | DAA(16) | — | CGI-MDT(0.3) | KBM- | F- |
| | | 3(11.87) | 960(5) | 280M(2) | | | | MX-270(0.4) | 303(0.4) | 477(300 ppm) |
| Example 4 | P-4 | A- | R- | TP5- | PGMEA(64) | DAA(16) | — | CGI-MDT(0.3) | KBM- | F- |
| | | 4(11.87) | 960(5) | 280M(2) | | | | MX-270(0.4) | 303(0.4) | 477(300 ppm) |
| Example 5 | P-5 | A- | R- | TP5- | PGMEA(64) | DAA(16) | — | CGI-MDT(0.3) | KBM- | F- |
| | | 5(11.87) | 960(5) | 280M(2) | | | | MX-270(0.4) | 303(0.4) | 477(300 ppm) |
| Example 6 | P-6 | A- | R- | TP5- | PGMEA(64) | DAA(16) | — | CGI-MDT(0.3) | KBM- | F- |
| | | 6(11.87) | 960(5) | 280M(2) | | | | MX-270(0.4) | 303(0.4) | 477(300 ppm) |
| Example 7 | P-7 | A- | R- | TP5- | PGMEA(64) | DAA(16) | — | CGI-MDT(0.3) | KBM- | F- |
| | | 1(6.87) | 960(10) | 280M(2) | | | | MX-270(0.4) | 303(0.4) | 477(300 ppm) |
| Example 8 | P-8 | A- | R- | TP5- | PGMEA(64) | DAA(16) | — | CGI-MDT(0.3) | KBM- | F- |
| | | 1(15.87) | 960(1) | 280M(2) | | | | MX-270(0.4) | 303(0.4) | 477(300 ppm) |
| Example 9 | P-9 | A- | CR- | TP5- | PGMEA(64) | DAA(16) | — | CGI-MDT(0.3) | KBM- | F- |
| | | 1(11.87) | 97(5) | 280M(2) | | | | MX-270(0.4) | 303(0.4) | 477(300 ppm) |
| Example 10 | P-10 | A- | 3Y1- | TP5- | PGMEA(64) | DAA(16) | — | CGI-MDT(0.3) | KBM- | F- |
| | | 1(11.87) | R(5) | 280M(2) | | | | MX-270(0.4) | 303(0.4) | 477(300 ppm) |
| Example 11 | P-11 | A- | AO- | TP5- | PGMEA(64) | DAA(16) | — | CGI-MDT(0.3) | KBM- | F- |
| | | 1(11.87) | 502(5) | 280M(2) | | | | MX-270(0.4) | 303(0.4) | 477(300 ppm) |
| Example 12 | P-12 | A- | R- | TP5- | PGMEA(64) | DAA(16) | — | CGI-MDT(0.3) | KBM- | F- |
| | | 1(12.87) | 960(5) | 280M(1) | | | | MX-270(0.4) | 303(0.4) | 477(300 ppm) |
| Example 13 | P-13 | A- | R- | TP5- | PGMEA(64) | DAA(16) | — | CGI-MDT(0.3) | KBM- | F- |
| | | 1(10.87) | 960(5) | 280M(3) | | | | MX-270(0.4) | 303(0.4) | 477(300 ppm) |

TABLE 4

| | Photosen- | | | | | | | | | |
|---|---|---|---|---|---|---|---|---|---|---|
| | sitive | Siloxane | Particles (B) | Naphtho- | | | | | | |
| | light- | resin/ | having median | quinone | | | | Other additives (wt %) | | |
| | diffusing | acrylic | diameter of | diazide | | | | | Adhesion | |
| | resin | resin (A) | 0.2 to 0.6 μm | compound | | | | Curing | improving | |
| | composition | (wt %) | (wt %) | (C) (wt %) | Organic solvent (wt %) | | | agent | agent | Surfactant |
| Comparative | P-14 | A- | R-960(5) | TP5- | PGMEA | DAA(16) | — | CGI-MDT(0.3) | KBM- | F-477 |
| Example 1 | | 7(11.87) | | 280M(2) | (64) | | | MX-270(0.4) | 303(0.4) | (300 ppm) |
| Comparative | P-15 | A- | R-960(5) | TP5- | PGMEA | DAA(16) | — | CGI-MDT(0.3) | KBM- | F-477 |
| Example 2 | | 8(11.87) | | 280M(2) | (64) | | | MX-270(0.4) | 303(0.4) | (300 ppm) |
| Comparative | P-16 | A- | R-960(5) | TP5- | PGMEA | DAA(16) | — | CGI-MDT(0.3) | KBM- | F-477 |
| Example 3 | | 9(11.87) | | 280M(2) | (64) | | | MX-270(0.4) | 303(0.4) | (300 ppm) |
| Comparative | P-17 | Acrylic | R-960(5) | TP5- | PGMEA | DAA(16) | — | CGI-MDT(0.3) | KBM- | F-477 |
| Example 4 | | resin (a) | | 280M(2) | (64) | | | MX-270(0.4) | 303(0.4) | (300 ppm) |
| | | (11.87) | | | | | | | | |
| Comparative | P-18 | A- | TR-550(5) | TP5- | PGMEA | DAA(16) | Methanol | CGI-MDT(0.3) | KBM- | F-477 |
| Example 5 | | 1(11.87) | | 280M(2) | (44) | | (20) | MX-270(0.4) | 303(0.4) | (300 ppm) |
| Comparative | P-19 | A- | — | TP5- | PGMEA | DAA(16) | — | CGI-MDT(0.3) | KBM- | F-477 |
| Example 6 | | 1(16.87) | | 280M(2) | (64) | | | MX-270(0.4) | 303(0.4) | (300 ppm) |
| Comparative | P-20 | A- | R-960(5) | — | PGMEA | DAA(16) | — | CGI-MDT(0.3) | KBM- | F-477 |
| Example 7 | | 1(13.87) | | | (64) | | | MX-270(0.4) | 303(0.4) | (300 ppm) |

TABLE 5

| | | Refractive | | | | | | | | |
|---|---|---|---|---|---|---|---|---|---|---|
| | | index of | | | | | | | | |
| | Refractive | particles | | | | | | | | |
| | index of | (B) having | Difference in | | | | | | | |
| | siloxane | median | refracttive | Median | Optimum | Pattern- | | | | |
| | resin/ | diameter | index | diameter of | exposure | ability | Resolution | | Resolution | |
| | acrylic | of 0.2 to | between | particles | amount | (development | after | | after | |
| | resin (A) | 0.6 μm | (A) and (B) | (B) (μm) | (mJ/cm²) | residue) | development | | curing | |
| Example 1 | 1.50 | 2.72 | 1.22 | 0.21 | 40 | 5 | 5 | μm | 5 | μm |
| Example 2 | 1.52 | 2.72 | 1.20 | 0.21 | 40 | 5 | 4 | μm | 4 | μm |
| Example 3 | 1.51 | 2.72 | 1.21 | 0.21 | 40 | 5 | 5 | μm | 7 | μm |
| Example 4 | 1.49 | 2.72 | 1.23 | 0.21 | 40 | 5 | 10 | μm | 10 | μm |
| Example 5 | 1.50 | 2.72 | 1.22 | 0.21 | 50 | 4 | 15 | μm | 15 | μm |
| Example 6 | 1.48 | 2.72 | 1.24 | 0.21 | 50 | 4 | 15 | μm | 15 | μm |
| Example 7 | 1.50 | 2.72 | 1.22 | 0.21 | 80 | 4 | 15 | μm | 15 | μm |
| Example 8 | 1.50 | 2.72 | 1.22 | 0.21 | 20 | 5 | 4 | μm | 4 | μm |
| Example 9 | 1.50 | 2.72 | 1.22 | 0.25 | 40 | 5 | 7 | μm | 7 | μm |
| Example 10 | 1.50 | 2.13 | 0.63 | 0.50 | 25 | 5 | 5 | μm | 5 | μm |
| Example 11 | 1.50 | 1.75 | 0.25 | 0.25 | 15 | 5 | 4 | μm | 4 | μm |
| Example 12 | 1.50 | 2.72 | 1.22 | 0.21 | 60 | 4 | 15 | μm | 15 | μm |
| Example 13 | 1.50 | 2.72 | 1.22 | 0.21 | 30 | 5 | 5 | μm | 5 | μm |

| | | | Heat | | Light | | | |
|---|---|---|---|---|---|---|---|---|
| | | | resistance | | resistance | | | |
| | | | Change | | Change | | | |
| | | | width | | width | | | |
| | Total | | (%) of | Change | (%) of | Change | | |
| | light | | total | width | total | width | | |
| | transmittance | Haze | light | (%) of | light | (%) of | Bendability | Storage |
| | (%) | (%) | transmittance | haze | transmittance | haze | (mm) | stability |
| Example 1 | 65.2 | 80.1 | 1.8 | 0.4 | 0.4 | 0.1 | 0.5 | A |
| Example 2 | 64.6 | 75.3 | 1.8 | 0.4 | 0.4 | 0.1 | 0.8 | A |
| Example 3 | 64.9 | 78.2 | 1.8 | 0.4 | 0.4 | 0.1 | 0.7 | A |
| Example 4 | 65.4 | 81.4 | 1.6 | 0.4 | 0.4 | 0.1 | 0.6 | A |
| Example 5 | 65.3 | 80.5 | 1.6 | 0.4 | 0.4 | 0.1 | 0.7 | B |
| Example 6 | 65.6 | 81.7 | 1.6 | 0.4 | 0.4 | 0.1 | 0.4 | A |
| Example 7 | 50.3 | 90.3 | 2.3 | 0.7 | 0.5 | 0.2 | 0.6 | A |
| Example 8 | 80.3 | 29.8 | 1.5 | 0.3 | 0.2 | 0.0 | 0.4 | A |
| Example 9 | 60.4 | 82.4 | 1.8 | 0.4 | 0.4 | 0.1 | 0.5 | A |
| Example 10 | 70.3 | 65.1 | 1.0 | 0.2 | 0.1 | 0.0 | 0.5 | A |
| Example 11 | 83.1 | 20.9 | 0.8 | 0.2 | 0.1 | 0.0 | 0.5 | A |
| Example 12 | 65.1 | 80.2 | 1.5 | 0.3 | 0.1 | 0.0 | 0.5 | A |
| Example 13 | 65.0 | 79.7 | 2.3 | 0.7 | 0.5 | 0.2 | 0.5 | A |

TABLE 6

| | | Refractive | | | | | | |
|---|---|---|---|---|---|---|---|---|
| | | index of | | | | | | |
| | Refractive | particles | | | | | | |
| | index of | (B) having | Difference in | | | | | |
| | siloxane | median | refracttive | Median | Optimum | Pattern- | | |
| | resin/ | diameter | index | diameter of | exposure | ability | Resolution | Resolution |
| | acrylic | of 0.2 to | between | particles | amount | (development | after | after |
| | resin (A) | 0.6 μm | (A) and (B) | (B) (μm) | (mJ/cm²) | residue) | development | curing |
| Comparative | 1.53 | 2.72 | 1.19 | 0.21 | 50 | 3 | 20 μm | 20 μm |
| Example 1 | | | | | | | | |
| Comparative | 1.49 | 2.72 | 1.23 | 0.21 | 50 | 3 | 40 μm | 40 μm |
| Example 2 | | | | | | | | |
| Comparative | 1.47 | 2.72 | 1.25 | 0.21 | 50 | 3 | 40 μm | 50 μm |
| Example 3 | | | | | | | | |
| Comparative | 1.51 | 2.72 | 1.21 | 0.21 | 50 | 3 | 30 μm | 40 μm |
| Example 4 | | | | | | | | |
| Comparative | 1.50 | 2.72 | 1.22 | 0.015 | 15 | 5 | 4 μm | 4 μm |
| Example 5 | | | | | | | | |
| Comparative | 1.50 | 2.72 | 1.22 | 0.21 | 10 | 5 | 4 μm | 4 μm |
| Example 6 | | | | | | | | |
| Comparative | 1.50 | 2.72 | 1.22 | 0.21 | — | 1 | >50 μm | >50 μm |
| Example 7 | | | | | | | | |

| | | | Heat | | Light | | | |
|---|---|---|---|---|---|---|---|---|
| | | | resistance | | resistance | | | |
| | | | Change | | Change | | | |
| | | | width | | width | | | |
| | Total | | (%) of | Change | (%) of | Change | | |
| | light | | total | width | total | width | | |
| | transmittance | Haze | light | (%) of | light | (%) of | Bendability | Storage |
| | (%) | (%) | transmittance | haze | transmittance | haze | (mm) | stability |
| Comparative | 64.4 | 74.9 | 2.0 | 0.5 | 0.4 | 0.1 | 0.5 | A |
| Example 1 | | | | | | | | |
| Comparative | 65.4 | 81.5 | 1.4 | 0.3 | 0.4 | 0.1 | 0.8 | A |
| Example 2 | | | | | | | | |
| Comparative | 66.0 | 82.1 | 1.4 | 0.3 | 0.4 | 0.1 | 0.5 | A |
| Example 3 | | | | | | | | |
| Comparative | 64.9 | 78.2 | 3.2 | 1.2 | 1.0 | 0.5 | 1.0 | A |
| Example 4 | | | | | | | | |
| Comparative | 96.8 | 1.5 | 1.8 | 0.4 | 0.4 | 0.1 | 0.5 | A |
| Example 5 | | | | | | | | |
| Comparative | 97.8 | 0.5 | 0.4 | 0.0 | 0.1 | 0.0 | 0.3 | A |
| Example 6 | | | | | | | | |
| Comparative | 65.3 | 77.1 | 1.4 | 0.3 | 0.4 | 0.1 | 0.5 | A |
| Example 7 | | | | | | | | |

### INDUSTRIAL APPLICABILITY

The cured film obtained by curing the photosensitive resin composition is suitably used as a material that diffuses light from a light emitting light source in lighting devices such as organic EL lighting and LED lighting, various display devices such as a laser display device and a liquid crystal display, and various other optical devices.

1-15. (canceled)

16. A photosensitive resin composition comprising:
a siloxane resin (A);
particles (B) having a median diameter of 0.2 to 0.6 μm; and
a naphthoquinone diazide compound (C),
wherein the siloxane resin (A) contains at least 20 to 60 mol % in total of a repeating unit represented by general formula (1), and
a content of the particles (B) having a median diameter of 0.2 to 0.6 μm in a total solid content of the photosensitive resin composition is 5 to 50 wt %: 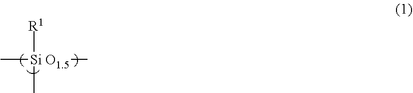
wherein R¹ represents an aryl group having 6 to 18 carbon atoms or an aryl group having 6 to 18 carbon atoms in which all or part of hydrogen is substituted.

17. The photosensitive resin composition according to claim 16, wherein a difference in refractive index between the siloxane resin (A) and the particles (B) having a median diameter of 0.2 to 0.6 μm is 0.20 to 1.40.

18. The photosensitive resin composition according to claim 16, wherein the particles (B) having a median diameter of 0.2 to 0.6 μm contain one or more selected from the group consisting of titanium dioxide, zirconium oxide, aluminum oxide, talc, isinglass (mica), white carbon, magnesium oxide, zinc oxide, barium carbonate, and composite compounds thereof.

19. The photosensitive resin composition according to claim 16, wherein the particles (B) having a median diameter of 0.2 to 0.6 μm contain at least one of titanium dioxide and zirconium oxide.

20. The photosensitive resin composition according to claim 16, wherein the siloxane resin (A) further contains 5 to 20 mol % in total of a repeating unit represented by general formula (2):

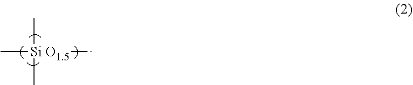

21. The photosensitive resin composition according to claim 16, wherein the siloxane resin (A) further contains 1 to 20 mol % in total of a repeating unit represented by general formula (3): 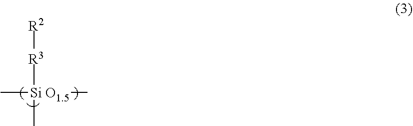
wherein R² represents an alkyl group, an alkenyl group, an aryl group, or an arylalkyl group wherein each group has 1 to 10 carbon atoms and in which all or part of hydrogen is substituted with fluorine, and R³ represents a single bond, —O—, —CH₂—CO—, —CO—, or —O—CO—.

22. The photosensitive resin composition according to claim 16, wherein a cured film of the photosensitive resin composition has a haze of 20 to 98% per 1 μm of film thickness.

23. A light diffusion layer comprising the photosensitive resin composition according to claim 16.

24. A cured film comprising a cured product of the photosensitive resin composition according to claim 16.

25. A method of producing a cured film, comprising:
(I) applying the photosensitive resin composition according to claim 16 onto a substrate to form a coating film;
(II) exposing and developing the coating film;
(III) re-exposing the developed coating film; and
(IV) heating the re-exposed coating film.

26. A substrate with a cured film comprising a substrate provided with a cured film patterned from the photosensitive resin composition according to claim 16 on the substrate, the cured film having a haze of 20 to 98% per 1 μm of film thickness.

27. The substrate with a cured film according to claim 26, wherein a film thickness of the cured film is 0.3 to 3.0 μm.

28. The substrate with a cured film according to claim 26, wherein the substrate is a glass substrate or a resin substrate containing polyimide.

29. The substrate with a cured film according to claim 26, further comprising a black layer between a piece of the cured film patterned on the substrate and an adjacent piece of the cured film.

30. A display device comprising:
the substrate with a cured film according to claim 26; and
a mini LED or a micro LED.
